(19) United States
(12) Patent Application Publication
(10) Pub. No.: US 2025/0350312 A1
(43) Pub. Date: Nov. 13, 2025

(54) RADIO FREQUENCY MODULE AND COMMUNICATION DEVICE

(71) Applicant: Murata Manufacturing Co., Ltd., Nagaokakyo-shi (JP)

(72) Inventors: Kouta ARAI, Nagaokakyo-shi (JP); Takeshi KOGURE, Nagaokakyo-shi (JP)

(21) Appl. No.: 19/273,265

(22) Filed: Jul. 18, 2025

Related U.S. Application Data
(63) Continuation of application No. PCT/JP2024/003763, filed on Feb. 5, 2024.

(30) Foreign Application Priority Data
Feb. 9, 2023 (JP) 2023-018622

(51) Int. Cl. H04B 1/401; H03F 1/02; H03F 3/24; H04B 1/04

(52) U.S. Cl. CPC H04B 1/401; H03F 1/02; H03F 3/24; H04B 1/04; H04B 2001/0408

(57) ABSTRACT

A radio frequency module is provided that includes a module laminate and first and second integrated circuits on the module laminate. The first integrated circuit includes at least one switch included in a converter circuit. The second integrated circuit includes a first amplifying transistor of a power amplifier that amplifies a radio frequency signal, and a second amplifying transistor of a low-noise amplifier that amplifies a radio frequency signal. The power amplifier is connected to an ET voltage generation circuit that generates a variable voltage based on an output voltage from the converter circuit and an envelope signal. The low-noise amplifier is connected to a constant voltage generation circuit that generates a constant voltage based on the output voltage from the converter circuit.

### CROSS REFERENCE TO RELATED APPLICATIONS

This application is a continuation of International Application No. PCT/JP2024/003763, filed Feb. 5, 2024, which claims priority to Japanese Patent Application No. 2023-018622, filed Feb. 9, 2023, the contents of each of which are hereby incorporated by reference in their entireties.

### TECHNICAL FIELD

The present disclosure relates to a radio frequency module and a communication device.

### BACKGROUND

The recent application of an envelope tracking (ET) mode to a power amplifier (PA) circuit has improved power amplification efficiency, such as described in U.S. Pat. No. 8,829,993.

However, when adding a receiving circuit including a low-noise amplifier to a power amplifier system (e.g., a radio frequency module) that operates in an ET mode, in addition to a transmitting circuit including a power amplifier (PA), the power amplifier system may be increased in size.

### SUMMARY OF THE INVENTION

In view of the foregoing, the exemplary aspects of the present disclosure provide a small radio frequency module and a small communication device having an ET mode power amplifier system.

In an exemplary aspect, a radio frequency module is provided that includes a module laminate; and a first integrated circuit and a second integrated circuit disposed on the module laminate. The first integrated circuit includes at least one switch included in a converter circuit, the second integrated circuit includes a first amplifying transistor of a power amplifier (PA) that amplifies a radio frequency signal, and a second amplifying transistor of a low-noise amplifier that amplifies a radio frequency signal. The power amplifier (PA) is connected to an ET voltage generation circuit that is configured to generate a variable voltage based on an output voltage from the converter circuit and an envelope signal, and the low-noise amplifier is connected to a constant voltage generation circuit that is configured to generate a constant voltage based on the output voltage from the converter circuit.

In another exemplary aspect, a radio frequency module is provided that includes a module laminate; and a first integrated circuit and a second integrated circuit disposed on the module laminate. The first integrated circuit has a first output terminal configured to output a variable voltage and a second output terminal configured to output a constant voltage. The second integrated circuit has a first input terminal connected to a power amplifier that is configured to amplify a radio frequency signal and a second input terminal connected to a low-noise amplifier that is configured to amplify a radio frequency signal. The first output terminal is connected to the first input terminal, and the second output terminal is connected to the second input terminal.

Accordingly, the exemplary aspects of the present disclosure provide a small radio frequency module and a small communication device having an ET mode power amplifier system.

### BRIEF DESCRIPTION OF DRAWINGS

FIG. 1A is a graph illustrating an example of the transition of a power supply voltage in an average power tracking (APT) mode.

FIG. 1B is a graph illustrating an example of the transition of the power supply voltage in an analog ET mode.

FIG. 1C is a graph illustrating an example of the transition of the power supply voltage in a digital ET mode.

FIG. 2 is a circuit configuration diagram of a radio frequency module and a communication device according to an exemplary embodiment.

FIG. 3 is a circuit configuration diagram of a tracker circuit according to the exemplary embodiment.

FIG. 4 is a diagram illustrating an example of a circuit configuration of a constant voltage generation circuit according to the exemplary embodiment.

FIG. 5 is a diagram illustrating an example of a circuit configuration of an analog ET voltage generation circuit according to the exemplary embodiment.

FIG. 6 is a diagram illustrating an example of a circuit configuration of a digital ET voltage generation circuit according to the exemplary embodiment.

FIG. 7 is a circuit configuration diagram of a converter circuit, a switched-capacitor circuit, a supply modulator, and a filter circuit according to the exemplary embodiment.

FIG. 8A is a plan view of a radio frequency module according to Example 1 of an exemplary aspect.

FIG. 8B is a cross-sectional view of the radio frequency module according to Example 1 of an exemplary aspect.

FIG. 9A is a plan view of a radio frequency module according to Example 2 of an exemplary aspect.

FIG. 9B is a cross-sectional view of the radio frequency module according to Example 2 of an exemplary aspect.

FIG. 10A is a plan view of a radio frequency module according to Example 3 of an exemplary aspect.

FIG. 10B is a plan view of the radio frequency module according to Example 3 of an exemplary aspect.

FIG. 10C is a cross-sectional view of the radio frequency module according to Example 3 of an exemplary aspect.

FIG. 11A is a plan view of a radio frequency module according to Example 4 of an exemplary aspect.

FIG. 11B is a cross-sectional view of the radio frequency module according to Example 4 of an exemplary aspect.

FIG. 12 is a cross-sectional view of a radio frequency module according to Example 5 of an exemplary aspect.

FIG. 13A is a plan view of a radio frequency module according to Example 6 of an exemplary aspect.

FIG. 13B is a plan view of the radio frequency module according to Example 6 of an exemplary aspect.

FIG. 13C is a cross-sectional view of the radio frequency module according to Example 6 of an exemplary aspect.

FIG. 14 is a cross-sectional view of a radio frequency module according to Example 7 of an exemplary aspect.

### DETAILED DESCRIPTION OF EMBODIMENTS

Hereinafter, embodiments of the present disclosure will be described in detail with reference to the drawings. The embodiments described below are all comprehensive or specific examples. The numerical values, shapes, materials, components, arrangement and connection forms of the components illustrated in the following embodiments are merely examples and are not intended to limit the exemplary aspects of the present disclosure.

It is noted that each drawing is a schematic diagram in which emphasis, omission, or ratio adjustment has been applied as needed to illustrate the exemplary aspects of the present disclosure, and is thus not necessarily an exact illustration. Shapes, positional relationships, and ratios of each drawing are different from the actual ones in some cases. In each drawing, substantially the same configurations are denoted by the same reference numerals, and repetitive description thereof is omitted or simplified in some cases.

In each drawing described below, an x-axis and a y-axis are axes orthogonal to each other on a plane parallel to the main surfaces of a module laminate. Specifically, when a module laminate has a rectangular shape in plan view, the x-axis is parallel to a first side of the module laminate, and the y-axis is parallel to a second side orthogonal to the first side of the module laminate. Further, a z-axis is an axis perpendicular to the main surfaces of the module laminate. The positive direction of the z-axis indicates the upward direction, and the negative direction thereof indicates the downward direction.

In circuit configurations of the present disclosure, the term “connected” not only indicates that circuit elements are directly connected to each other with a connection terminal and/or a wire conductor, but it can also indicate that the circuit elements are electrically connected to each other via another circuit element according to an exemplary aspect. Also, the phrase “connected between A and B” indicates that a component is disposed between A and B and connected to both of A and B according to an exemplary aspect.

According to the exemplary aspects, in terms of the component placement of the present disclosure, the phrase “a component is placed on a substrate” includes a case where the component is placed on the main surface of the substrate and a case where the component is placed within the substrate. Specifically, the phrase “a component is placed on a substrate” includes, in addition to the case where the component is placed on the main surface of the substrate while being in contact with the main surface, the case where the component is placed above the main surface without being in contact with the main surface (for example, the component is stacked on another component placed in contact with the main surface). Further, the phrase “a component is placed on the main surface of a substrate” may include a case where a component is placed in a recess formed in the main surface. Moreover, the phrase “a component is placed within a substrate” includes a case where the component is encapsulated within a module laminate, as well as a case where the component is entirely placed between both main surfaces of the substrate but not entirely covered by the substrate, and a case where the component is only partially placed within the substrate.

In the present disclosure, the phrase “component (element) A is disposed in series with path B” can indicate that each of a signal input end and a signal output end of the component (element) A is connected to one of wiring, an electrode, and a terminal forming the path B according to an exemplary aspect.

Moreover, in terms of the component placement of the exemplary aspects of the present disclosure, the phrase “plan view of the module laminate” can refer to viewing an object or component orthographically projected on the xy plane from the positive side of the z-axis. Moreover, the phrase “A overlaps B in plan view” can indicate that at least a part of the region of A orthographically projected on the xy plane overlaps at least a part of the region of B orthographically projected on the xy plane. Further, the phrase “A is disposed between B and C” can indicate that at least one of a plurality of line segments connecting any point in B and any point in C passes through A according to an exemplary aspect.

Further, in terms of the component placement of the exemplary aspects of the present disclosure, the phrase “A is disposed adjacent to B” can indicate that A and B are disposed in proximity to each other, and specifically can indicate that no other circuit components are present in the space where A faces B according to an exemplary aspect. In other words, the phrase “A is disposed adjacent to B” can indicate that none of a plurality of line segments that reach B from any point on a surface of A facing B along the normal direction of the surface passes through circuit components other than A and B. Here, the circuit components refer to components including active elements and/or passive elements. In other words, the circuit components include active components including transistors, diodes or the like, and passive components including inductors, transformers, capacitors, resistors or the like, but do not include electromechanical components including terminals, connectors, wiring or the like.

According to the exemplary aspects of the present disclosure, the term “terminal” refers to a point at which a conductor in an element ends. It is noted that when the impedance of the conductor between elements is sufficiently low, the terminal is interpreted not only as a single point, but also as any point on the conductor between elements or the entire conductor.

Further, terms indicating the relationship between elements, such as “parallel” and “perpendicular”, terms indicating the shapes of elements such as “rectangle”, and numerical value ranges do not only represent the strict meanings but also include substantially equivalent ranges with errors of about several percent, for example.

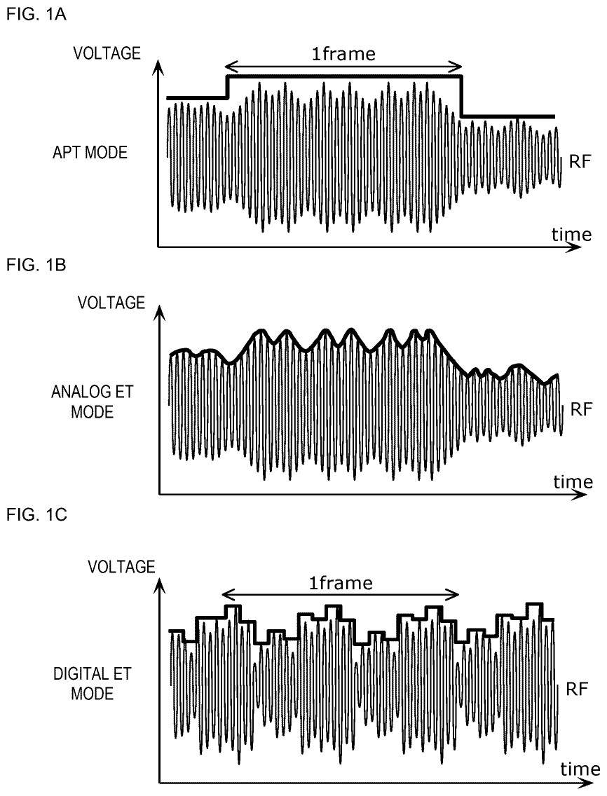

First, as a technology for amplifying a radio frequency (RF) signal with high efficiency, a description will be given of a tracking mode for supplying a power amplifier (PA) with a power supply voltage that is dynamically adjusted over time in accordance with the RF signal. The tracking mode is a mode for dynamically adjusting the power supply voltage applied to the PA. While there are several types of tracking modes, an average power tracking (APT) mode and an envelope tracking (ET) mode (including an analog ET mode and a digital ET mode) will be described here with reference to FIGS. 1A to 1C. In FIGS. 1A to 1C, the horizontal axis represents time and the vertical axis represents voltage. The thick solid line represents the power supply voltage, while the thin solid line (waveform) represents a modulated signal.

FIG. 1A is a graph illustrating an example of the transition of the power supply voltage in the APT mode. In the APT mode, the power supply voltage is varied to a plurality of discrete voltage levels in units of one frame, based on the average power. As a result, a power supply voltage signal forms a rectangular wave.

In an exemplary aspect, a frame refers to a unit that forms a radio frequency (RF) signal (e.g., a modulated signal). For example, in 5GNR (5th Generation New Radio) and LTE (Long Term Evolution), a frame includes 10 subframes, each subframe includes more than one slot, and each slot includes more than one symbol. The subframe length is 1 milliseconds (ms), and the frame length is 10 ms.

It is noted that a mode for changing the voltage level in units of one frame or larger based on the average power is referred to as the APT mode, and is distinguished from a mode for changing the voltage level in units smaller than one frame (such as the subframe, slot, or symbol). For example, a mode for changing the voltage level in units of symbols is referred to as a symbol power tracking (SPT) mode, and is distinguished from the APT mode.

FIG. 1B is a graph illustrating an example of the transition of the power supply voltage in the analog ET mode. In the analog ET mode, an envelope of the modulated signal is tracked by continuously changing the power supply voltage based on an envelope signal.

The envelope signal is a signal indicating the envelope of the modulated signal. The envelope value is expressed as the square root of (I²+Q²), for example. Here, (I, Q) represents a constellation point. The constellation point is a point on a constellation diagram that represents a signal modulated by digital modulation. (I, Q) is determined by a baseband integrated circuit (BBIC), for example, based on transmission information, for example.

FIG. 1C is a graph illustrating an example of the transition of the power supply voltage in the digital ET mode. In the digital ET mode, the envelope of the modulated signal is tracked by varying the power supply voltage to a plurality of discrete voltage levels within one frame, based on the envelope signal. As a result, the power supply voltage signal forms a rectangular wave.

### EXEMPLARY EMBODIMENT

A communication device 4 according to this embodiment corresponds to a user equipment (UE) that communicates with other terminals and base stations by using radio signals in the millimeter wave band or the sub-terahertz band. The communication device 4 is typically a mobile phone, a smartphone, a tablet computer, a wearable device, or the like. The communication device 4 may also be an IoT (Internet of Things) sensor device, a medical/healthcare device, a car, an unmanned aerial vehicle (UAV) (so-called drone), or an automated guided vehicle (AGV). The communication device 4 may also function as a base station. The communication device 4 may also be a UE or a base station in a cellular network.

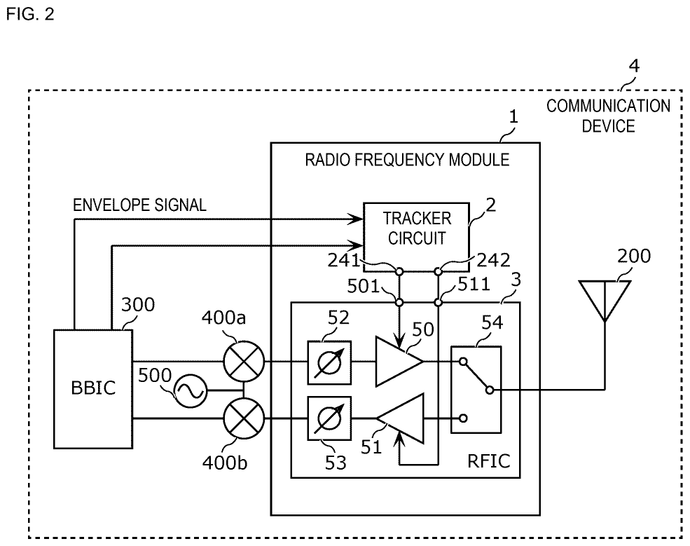

A circuit configuration of the communication device 4 and a radio frequency module 1 according to this embodiment will be described with reference to FIG. 2. FIG. 2 is a circuit configuration diagram of the radio frequency module 1 and the communication device 4 according to the embodiment.

It is noted that FIG. 2 illustrates an exemplary circuit configuration, and the communication device 4 and the radio frequency module 1 can be implemented using any of a wide variety of circuit implementations and circuit technologies. Therefore, the description of the communication device 4 and the radio frequency module 1 provided below should not be construed as being limiting.

### 1. Circuit Configuration of Communication Device 4 and Radio Frequency Module 1

First, the communication device 4 according to the embodiment will be described with reference to FIG. 2. The communication device 4 includes the radio frequency module 1, an antenna 200, a baseband signal integrated circuit (BBIC) 300, mixers 400a and 400b, and a local oscillator 500.

The radio frequency module 1 includes a tracker circuit 2 and an RFIC (Radio Frequency Integrated Circuit) 3.

The RFIC 3 is an example of a signal processing circuit, and includes phase shift circuits 52 and 53, a power amplifier (PA) 50, a low-noise amplifier 51, and a switch 54. The RFIC 3 is configured to output a radio frequency signal to the antenna 200.

The phase shift circuit 52 adjusts the phase of a radio frequency transmission signal outputted from the mixer 400a. The phase shift circuit 53 adjusts the phase of a radio frequency reception signal outputted from the low-noise amplifier 51.

The PA 50 amplifies the radio frequency transmission signal outputted from the phase shift circuit 52. The low-noise amplifier 51 amplifies the radio frequency reception signal outputted from the antenna 200.

The switch 54 switches the connection between the antenna 200 and the output end of the PA 50, and the connection between the antenna 200 and the input end of the low-noise amplifier 51.

In an exemplary aspect, the PA 50 and the low-noise amplifier 51 are configured to amplify radio frequency (RF) signals in the millimeter wave band and the sub-terahertz band. Moreover, the PA 50 and the low-noise amplifier 51 are configured to amplify RF signals in a frequency band predefined by a standardizing body (for example, 3GPP® (3rd Generation Partnership Project), IEEE (Institute of Electrical and Electronics Engineers) or the like) for a communication system built using a radio access technology (RAT).

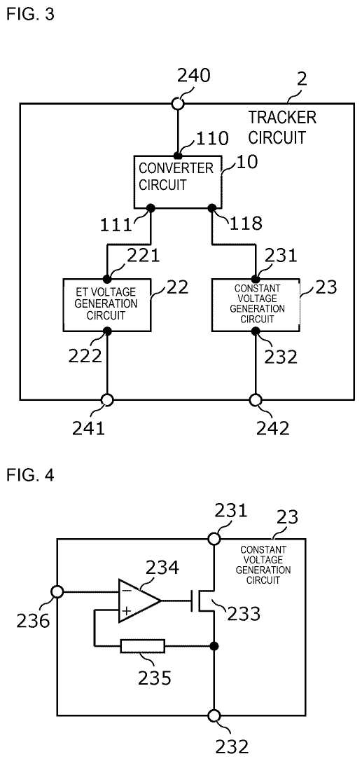

The tracker circuit 2 generates a supply voltage to the PA 50 and the low-noise amplifier 51, which amplify radio frequency signals, and is composed of at least one integrated circuit. Specifically, the tracker circuit 2 supplies a variable voltage to the PA 50 in the digital ET mode or the analog ET mode, based on an envelope signal supplied from the BBIC 300. The tracker circuit 2 also supplies a constant voltage to the low-noise amplifier 51. A circuit configuration example of the tracker circuit 2 will be described later with reference to FIGS. 3 to 7.

It is noted that at least one of the PA 50, the low-noise amplifier 51, and the switch 54 may be omitted from the RFIC 3 in an exemplary aspect.

The antenna 200 outputs the radio frequency transmission signal outputted from the radio frequency module 1, and also outputs the received radio frequency reception signal to the radio frequency module 1. It is noted that the antenna 200 may be omitted from the communication device 4 in an exemplary aspect.

The BBIC 300 is an integrated circuit that generates a baseband transmission signal and processes a baseband reception signal. The BBIC 300 also supplies an envelope signal to the tracker circuit 2 of the radio frequency module 1.

The mixer 400a up-converts the transmission signal generated by the BBIC 300, based on a local oscillation wave from the local oscillator 500, and outputs the up-converted transmission signal to a transmission path of the RFIC 3. The mixer 400b down-converts the reception signal outputted from a receive path of the RFIC 3, based on the local oscillation wave from the local oscillator 500, and outputs the down-converted reception signal to the BBIC 300.

It is noted that at least one of the mixers 400a and 400b and the local oscillator 500 may be included in the RFIC 3 in an exemplary aspect.

In the above configuration, the communication device 4 further includes a motherboard. The radio frequency module 1 is disposed on the motherboard and configured to transmit a radio frequency signal to the antenna 200 and to transmit a radio frequency signal from the antenna 200.

### 2. Circuit Configuration of Tracker Circuit 2

FIG. 3 is a circuit configuration diagram of the tracker circuit according to the embodiment. The tracker circuit 2 includes a converter circuit 10, an ET voltage generation circuit 22, a constant voltage generation circuit 23, an input terminal 240, and output terminals 241 and 242.

The converter circuit 10 has an input terminal 110 and output terminals 111 and 118, converts a DC voltage received from the input terminal 110, and outputs the converted voltage as an output voltage to the output terminals 111 and 118.

The constant voltage generation circuit 23 has an input terminal 231 and an output terminal 232, and is configured to output from the output terminal 232 a constant voltage lower than the maximum value of the output voltage from the converter circuit 10. The constant voltage generation circuit 23 is connected to the low-noise amplifier 51 via the output terminals 232 and 242.

The ET voltage generation circuit 22 has an input terminal 221 and an output terminal 222, and is configured to output a variable voltage from the output terminal 222 based on the output voltage from the converter circuit 10, the envelope signal, and the tracking mode. The ET voltage generation circuit 22 is connected to the PA 50 via the output terminals 222 and 241.

Next, a circuit configuration example of the constant voltage generation circuit 23 will be described.

FIG. 4 is a diagram illustrating a circuit configuration example of the constant voltage generation circuit 23 according to the embodiment. As illustrated in FIG. 4, the constant voltage generation circuit 23 includes an output driver circuit 233, an operational amplifier circuit 234, a feedback circuit 235, the input terminal 231, the output terminal 232, and a control terminal 236.

The output driver circuit 233 is composed of, for example, a transistor having a control terminal, a first terminal, and a second terminal.

The operational amplifier circuit 234 is composed of, for example, an operational amplifier having a third terminal, a fourth terminal, and an output terminal.

The feedback circuit 235 is composed of, for example, a resistive element.

The control terminal of the output driver circuit 233 is connected to the output terminal of the operational amplifier circuit 234, the first terminal is connected to the input terminal 231, and the second terminal is connected to the output terminal 232. The third terminal is connected to the control terminal 236, the fourth terminal is connected to one end of the feedback circuit 235, and the other end of the feedback circuit 235 is connected to the second terminal.

With the above configuration, a constant voltage with a limited upper limit is outputted to the output terminal 232. Specifically, the output driver circuit 233 is configured to output a constant voltage lower than the maximum value of the output voltage of the converter circuit 10 to the output terminal 232.

Next, two types of circuit configuration examples of the ET voltage generation circuit 22 will be described. A first circuit configuration example is a circuit configuration where the tracking mode is the analog ET mode, and the ET voltage generation circuit 22 has a configuration of an analog ET voltage generation circuit 22A. A second circuit configuration example is a circuit configuration where the tracking mode is the digital ET mode, and the ET voltage generation circuit 22 has a configuration of a digital ET voltage generation circuit 22B.

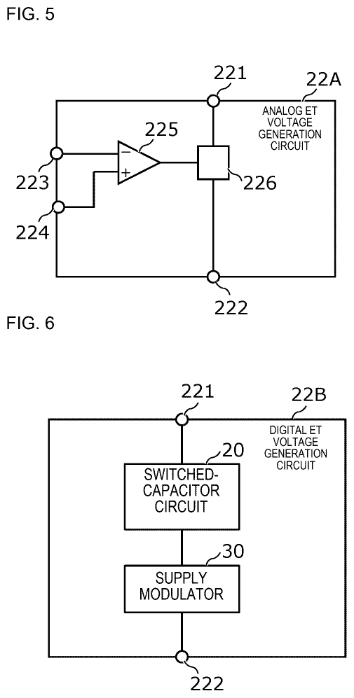

FIG. 5 is a diagram illustrating a circuit configuration example of the analog ET voltage generation circuit 22A according to the embodiment. As illustrated in FIG. 5, the analog ET voltage generation circuit 22A includes a linear amplifier circuit 225, a synthesis circuit 226, an input terminal 221, an output terminal 222, an envelope signal terminal 223, and a feedback terminal 224.

The linear amplifier circuit 225 is configured to linearly amplify a signal corresponding to the envelope signal received from the envelope signal terminal 223, and to output the linearly amplified voltage to the synthesis circuit 226.

The synthesis circuit 226 is configured to synthesize the linearly amplified voltage and the output voltage from the converter circuit 10, and to output a variable voltage based on the envelope signal to the output terminal 222.

FIG. 6 is a diagram illustrating a circuit configuration example of the digital ET voltage generation circuit 22B according to the embodiment. As illustrated in FIG. 6, the digital ET voltage generation circuit 22B includes a switched-capacitor circuit 20, a supply modulator 30, an input terminal 221, and an output terminal 222.

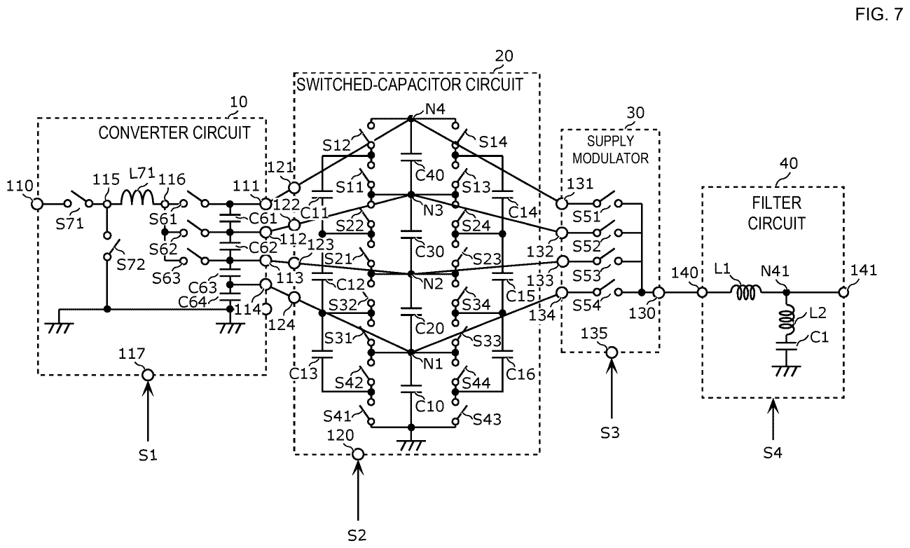

FIG. 7 is a circuit configuration diagram of the converter circuit 10, the switched-capacitor circuit 20, the supply modulator 30, and the filter circuit 40 according to the embodiment. FIG. 7 illustrates a circuit configuration example of the digital ET voltage generation circuit 22B, the converter circuit 10, and the filter circuit 40 where the tracking mode is the digital ET mode.

In an exemplary aspect, the tracker circuit 2 is configured to supply a plurality of discrete voltages to the PA 50 based on the digital ET mode.

It is noted that FIG. 7 illustrates an exemplary circuit configuration, and the converter circuit 10, the switched-capacitor circuit 20, the supply modulator 30, and the filter circuit 40 can be implemented using any of a wide variety of circuit implementations and circuit technologies. Therefore, the description of each circuit provided below should not be construed as being limiting.

It is noted that the tracker circuit 2 may include the filter circuit 40, or may omit the filter circuit 40 in an exemplary aspect. Any combination of the converter circuit 10, the switched-capacitor circuit 20, the supply modulator 30, and the filter circuit 40 may be integrated into a single circuit. The tracker circuit 2 may also include a plurality of voltage supply circuits, instead of the converter circuit 10 and the switched-capacitor circuit 20. In this case, the supply modulator 30 may be configured to select at least one of the plurality of voltage supply circuits.

### [2.1 Circuit Configuration of Switched-Capacitor Circuit 20]

The switched-capacitor circuit 20 includes a plurality of capacitors and a plurality of switches, and can generate a plurality of second voltages, each having a plurality of discrete voltage levels, as a plurality of discrete voltages, from a first voltage from the converter circuit 10. The switched-capacitor circuit 20 is sometimes called a switched-capacitor voltage balancer.

As illustrated in FIG. 7, the switched-capacitor circuit 20 includes capacitors C11 to C16, capacitors C10, C20, C30, and C40, and switches S11 to S14, S21 to S24, S31 to S34, and S41 to S44. Energy and electric charges are received from the converter circuit 10 to the switched-capacitor circuit 20 at nodes N1 to N4, and are drawn from the switched-capacitor circuit 20 to the supply modulator 30 at the nodes N1 to N4.

The capacitors C11 to C16 each function as a flying capacitor (sometimes called a transfer capacitor). That is, the capacitors C11 to C16 are each used to step up or step down the first voltage supplied from the converter circuit 10. More specifically, the capacitors C11 to C16 transfer charges between the capacitors C11 to C16 and the nodes N1 to N4, so that voltages V1 to V4 (voltages with respect to a ground potential) that satisfy V1:V2:V3:V4=1:2:3:4 are maintained at the four nodes N1 to N4. These voltages V1 to V4 correspond to a plurality of second voltages, each having a plurality of discrete voltage levels.

The capacitor C11 has two electrodes. One of the two electrodes of the capacitor C11 is connected to one end of the switch S11 and one end of the switch S12. The other of the two electrodes of the capacitor C11 is connected to one end of the switch S21 and one end of the switch S22.

The capacitor C12 has two electrodes. One of the two electrodes of the capacitor C12 is connected to the one end of the switch S21 and the one end of the switch S22. The other of the two electrodes of the capacitor C12 is connected to one end of the switch S31 and one end of the switch S32.

The capacitor C13 has two electrodes. One of the two electrodes of the capacitor C13 is connected to the one end of the switch S31 and the one end of the switch S32. The other of the two electrodes of the capacitor C13 is connected to one end of the switch S41 and one end of the switch S42.

The capacitor C14 has two electrodes. One of the two electrodes of the capacitor C14 is connected to one end of the switch S13 and one end of the switch S14. The other of the two electrodes of the capacitor C14 is connected to one end of the switch S23 and one end of the switch S24.

The capacitor C15 has two electrodes. One of the two electrodes of the capacitor C15 is connected to the one end of the switch S23 and the one end of the switch S24. The other of the two electrodes of the capacitor C15 is connected to one end of the switch S33 and one end of the switch S34.

The capacitor C16 has two electrodes. One of the two electrodes of the capacitor C16 is connected to the one end of the switch S33 and the one end of the switch S34. The other of the two electrodes of the capacitor C16 is connected to one end of the switch S43 and one end of the switch S44.

A set of the capacitors C11 and C14, a set of the capacitors C12 and C15, and a set of the capacitors C13 and C16 can each be charged and discharged in a complementary manner as a result of a first phase and a second phase being repeated.

Specifically, in the first phase, the switches S12, S13, S22, S23, S32, S33, S42, and S43 are turned ON. Accordingly, for example, the one of the two electrodes of the capacitor C12 is connected to the node N3, the other of the two electrodes of the capacitor C12 and the one of the two electrodes of the capacitor C15 are connected to the node N2, and the other of the two electrodes of the capacitor C15 is connected to the node N1.

On the other hand, in the second phase, the switches S11, S14, S21, S24, S31, S34, S41, and S44 are turned ON. Accordingly, for example, the one of the two electrodes of the capacitor C15 is connected to the node N3, the other of the two electrodes of the capacitor C15 and the one of the two electrodes of the capacitor C12 are connected to the node N2, and the other of the two electrodes of the capacitor C12 is connected to the node N1.

As a result of the first phase and the second phase being repeated, for example, when one of the capacitors C12 and C15 is charged through the node N2, the other of the capacitors C12 and C15 can be discharged to the capacitor C30. In short, the capacitors C12 and C15 can be charged and discharged in a complementary manner.

Similarly to the set of the capacitors C12 and C15, the set of the capacitors C11 and C14 and the set of the capacitors C13 and C16 can each be charged and discharged in a complementary manner as a result of the first phase and the second phase being repeated.

The capacitors C10, C20, C30, and C40 each function as a smoothing capacitor. Specifically, the capacitors C10, C20, C30, and C40 are used to hold and smooth the voltages V1 to V4 at the nodes N1 to N4, respectively.

The capacitor C10 is connected between the node N1 and ground. Specifically, one of the two electrodes of the capacitor C10 is connected to the node N1. On the other hand, the other of the two electrodes of the capacitor C10 is connected to ground.

The capacitor C20 is connected between the nodes N2 and N1. Specifically, one of the two electrodes of the capacitor C20 is connected to the node N2. On the other hand, the other of the two electrodes of the capacitor C20 is connected to the node N1.

The capacitor C30 is connected between the nodes N3 and N2. Specifically, one of the two electrodes of the capacitor C30 is connected to the node N3. On the other hand, the other of the two electrodes of the capacitor C30 is connected to the node N2.

The capacitor C40 is connected between the nodes N4 and N3. Specifically, one of the two electrodes of the capacitor C40 is connected to the node N4. On the other hand, the other of the two electrodes of the capacitor C40 is connected to the node N3.

The switch S11 is connected between the one of the two electrodes of the capacitor C11 and the node N3. Specifically, the one end of the switch S11 is connected to the one of the two electrodes of the capacitor C11. On the other hand, the other end of the switch S11 is connected to the node N3.

The switch S12 is connected between the one of the two electrodes of the capacitor C11 and the node N4. Specifically, the one end of the switch S12 is connected to the one of the two electrodes of the capacitor C11. On the other hand, the other end of the switch S12 is connected to the node N4.

The switch S21 is connected between the one of the two electrodes of the capacitor C12 and the node N2. Specifically, the one end of the switch S21 is connected to the one of the two electrodes of the capacitor C12 and the other of the two electrodes of the capacitor C11. On the other hand, the other end of the switch S21 is connected to the node N2.

The switch S22 is connected between the one of the two electrodes of the capacitor C12 and the node N3. Specifically, the one end of the switch S22 is connected to the one of the two electrodes of the capacitor C12 and the other of the two electrodes of the capacitor C11. On the other hand, the other end of the switch S22 is connected to the node N3.

The switch S31 is connected between the other of the two electrodes of the capacitor C12 and the node N1. Specifically, the one end of the switch S31 is connected to the other of the two electrodes of the capacitor C12 and the one of the two electrodes of the capacitor C13. On the other hand, the other end of the switch S31 is connected to the node N1.

The switch S32 is connected between the other of the two electrodes of the capacitor C12 and the node N2. Specifically, the one end of the switch S32 is connected to the other of the two electrodes of the capacitor C12 and the one of the two electrodes of the capacitor C13. On the other hand, the other end of the switch S32 is connected to the node N2. That is, the other end of the switch S32 is connected to the other end of the switch S21.

The switch S41 is connected between the other of the two electrodes of the capacitor C13 and ground. Specifically, the one end of the switch S41 is connected to the other of the two electrodes of the capacitor C13. On the other hand, the other end of the switch S41 is connected to ground.

The switch S42 is connected between the other of the two electrodes of the capacitor C13 and the node N1. Specifically, the one end of the switch S42 is connected to the other of the two electrodes of the capacitor C13. On the other hand, the other end of the switch S42 is connected to the node N1. That is, the other end of the switch S42 is connected to the other end of the switch S31.

The switch S13 is connected between the one of the two electrodes of the capacitor C14 and the node N3. Specifically, the one end of the switch S13 is connected to the one of the two electrodes of the capacitor C14. On the other hand, the other end of the switch S13 is connected to the node N3. That is, the other end of the switch S13 is connected to the other end of the switch S11 and the other end of the switch S22.

The switch S14 is connected between the one of the two electrodes of the capacitor C14 and the node N4. Specifically, the one end of the switch S14 is connected to the one of the two electrodes of the capacitor C14. On the other hand, the other end of the switch S14 is connected to the node N4. That is, the other end of the switch S14 is connected to the other end of the switch S12.

The switch S23 is connected between the one of the two electrodes of the capacitor C15 and the node N2. Specifically, the one end of the switch S23 is connected to the one of the two electrodes of the capacitor C15 and the other of the two electrodes of the capacitor C14. On the other hand, the other end of the switch S23 is connected to the node N2. That is, the other end of the switch S23 is connected to the other end of the switch S21 and the other end of the switch S32.

The switch S24 is connected between the one of the two electrodes of the capacitor C15 and the node N3. Specifically, the one end of the switch S24 is connected to the one of the two electrodes of the capacitor C15 and the other of the two electrodes of the capacitor C14. On the other hand, the other end of the switch S24 is connected to the node N3. That is, the other end of the switch S24 is connected to the other end of the switch S11, the other end of the switch S22, and the other end of the switch S13.

The switch S33 is connected between the other of the two electrodes of the capacitor C15 and the node N1. Specifically, the one end of the switch S33 is connected to the other of the two electrodes of the capacitor C15 and the one of the two electrodes of the capacitor C16. On the other hand, the other end of the switch S33 is connected to the node N1. That is, the other end of the switch S33 is connected to the other end of the switch S31 and the other end of the switch S42.

The switch S34 is connected between the other of the two electrodes of the capacitor C15 and the node N2. Specifically, the one end of the switch S34 is connected to the other of the two electrodes of the capacitor C15 and the one of the two electrodes of the capacitor C16. On the other hand, the other end of the switch S34 is connected to the node N2. That is, the other end of the switch S34 is connected to the other end of the switch S21, the other end of the switch S32, and the other end of the switch S23.

The switch S43 is connected between the other of the two electrodes of the capacitor C16 and ground. Specifically, the one end of the switch S43 is connected to the other of the two electrodes of the capacitor C16. On the other hand, the other end of the switch S43 is connected to ground.

The switch S44 is connected between the other of the two electrodes of the capacitor C16 and the node N1. Specifically, the one end of the switch S44 is connected to the other of the two electrodes of the capacitor C16. On the other hand, the other end of the switch S44 is connected to the node N1. That is, the other end of the switch S44 is connected to the other end of the switch S31, the other end of the switch S42, and the other end of the switch S33.

The switches S11, S12, S13, S14, S21, S22, S23, and S24 are at least one switch included in the switched-capacitor circuit 20.

A first set of switches including the switches S12, S13, S22, S23, S32, S33, S42, and S43, and a second set of switches including the switches S11, S14, S21, S24, S31, S34, S41, and S44 are turned ON and OFF in a complementary manner based on a control signal S2. Specifically, in the first phase, the switches in the first set are turned ON whereas the switches in the second set are turned OFF. Conversely, in the second phase, the switches in the first set are turned OFF whereas the switches in the second set are turned ON.

For example, in one of the first phase and the second phase, charging from the capacitors C11 to C13 to the capacitors C10 to C40 is performed, and in the other of the first phase and the second phase, charging from the capacitors C14 to C16 to the capacitors C10 to C40 is performed. In other words, because the capacitors C10 to C40 are constantly charged by the capacitors C11 to C13 or the capacitors C14 to C16, the nodes N1 to N4 are rapidly replenished with electric charges even when currents rapidly flow from the nodes N1 to N4 to the supply modulator 30. Thus, potential variations at the nodes N1 to N4 can be reduced.

As a result of operating in the above-described manner, the switched-capacitor circuit 20 is configured to maintain substantially equal voltages across each of the capacitors C10, C20, C30, and C40. Specifically, the voltages V1 to V4 (voltages with respect to a ground potential) satisfying V1:V2:V3:V4=1:2:3:4 are maintained at the four nodes labeled V1 to V4. The levels of the voltages V1 to V4 correspond to a plurality of discrete voltage levels that can be supplied to the supply modulator 30 by the switched-capacitor circuit 20.

It is noted that the voltage ratio V1:V2:V3:V4 is not limited to 1:2:3:4. For example, the voltage ratio V1:V2:V3:V4 may be 1:2:4:8 in an alternative aspect.

The configuration of the switched-capacitor circuit 20 illustrated in FIG. 7 is illustrative and is not restrictive. In FIG. 7, the switched-capacitor circuit 20 is configured to supply voltages of four discrete voltage levels, but the configuration is not limited thereto. The switched-capacitor circuit 20 may be configured to supply voltages of any number of two or more discrete voltage levels. For example, in the case of supplying voltages of two discrete voltage levels, it is sufficient that the switched-capacitor circuit 20 include at least the capacitors C12 and C15 and the switches S21 to S24 and S31 to S34.

### [2.2 Circuit Configuration of Supply Modulator 30]

The supply modulator 30 is configured to selectively output at least one of the plurality of discrete voltages generated by the switched-capacitor circuit 20 to the PA 50. The supply modulator 30 is controlled based on a digital control signal.

As illustrated in FIG. 7, the supply modulator 30 includes input terminals 131 to 134, switches S51 to S54, and an output terminal 130.

The output terminal 130 is connected to an input terminal 140 of the filter circuit 40. The output terminal 130 is a terminal for supplying the PA 50 through the filter circuit 40 with a power supply voltage selected from among the voltages V1 to V4.

The input terminals 131 to 134 are connected to the nodes N4 to N1 of the switched-capacitor circuit 20, respectively. The input terminals 131 to 134 are terminals for receiving the voltages V4 to V1 from the switched-capacitor circuit 20, respectively.

The switch S51 is connected between the input terminal 131 and the output terminal 130. Specifically, the switch S51 has a terminal connected to the input terminal 131 and a terminal connected to the output terminal 130. In this connection configuration, ON/OFF switching of the switch S51 based on a control signal S3 enables switching between connection and disconnection between the input terminal 131 and the output terminal 130.

The switch S52 is connected between the input terminal 132 and the output terminal 130. Specifically, the switch S52 has a terminal connected to the input terminal 132 and a terminal connected to the output terminal 130. In this connection configuration, ON/OFF switching of the switch S52 based on the control signal S3 enables switching between connection and disconnection between the input terminal 132 and the output terminal 130.

The switch S53 is connected between the input terminal 133 and the output terminal 130. Specifically, the switch S53 has a terminal connected to the input terminal 133 and a terminal connected to the output terminal 130. In this connection configuration, ON/OFF switching of the switch S53 based on the control signal S3 enables switching between connection and disconnection between the input terminal 133 and the output terminal 130.

The switch S54 is connected between the input terminal 134 and the output terminal 130. Specifically, the switch S54 has a terminal connected to the input terminal 134 and a terminal connected to the output terminal 130. In this connection configuration, ON/OFF switching of the switch S54 based on the control signal S3 enables switching between connection and disconnection between the input terminal 134 and the output terminal 130.

The switches S51 and S52 are at least one switch included in the supply modulator 30.

These switches S51 to S54 are controlled so as to be exclusively turned ON. In other words, only any one of the switches S51 to S54 is turned ON, and the others are turned OFF. Accordingly, the supply modulator 30 is configured to output one voltage selected from among the voltages V1 to V4.

The configuration of the supply modulator 30 illustrated in FIG. 7 is illustrative, and is not restrictive. In particular, the switches S51 to S54 may have any configuration as long as at least one of the four input terminals 131 to 134 can be selected and connected to the output terminal 130. For example, the supply modulator 30 may further include a switch connected between a set of the switches S51 to S53 and a set of the switch S54 and the output terminal 130. For example, the supply modulator 30 may further include a switch connected between a set of the switches S51 and S52 and a set of the switches S53 and S54 and the output terminal 130.

In an exemplary aspect, when voltages of two discrete voltage levels are supplied from the switched-capacitor circuit 20, it is sufficient that the supply modulator 30 include at least two of the switches S51 to S54.

### [2.3 Circuit Configuration of Converter Circuit 10]

The converter circuit 10 is an example of a converter circuit, and includes a power inductor and switches. The power inductor is an inductor used to step up and/or step down a direct current (DC) voltage. The power inductor is connected in series to a direct current (DC) path. The power inductor may be connected (disposed in parallel) between the DC path and ground. The converter circuit 10 can convert an input voltage to a first voltage using the power inductor. Such a converter circuit 10 is also sometimes called a magnetic regulator or a DC/DC converter.

As illustrated in FIG. 7, the converter circuit 10 includes an input terminal 110, output terminals 111 to 114, inductor connection terminals 115 and 116, switches S61 to S63, S71, and S72, a power inductor L71, and capacitors C61 to C64.

The input terminal 110 is an input terminal for a DC voltage. Specifically, the input terminal 110 is a terminal for receiving an input voltage from a direct current (DC) power source.

The output terminal 111 is an output terminal for the voltage V4. Specifically, the output terminal 111 is a terminal for supplying the voltage V4 to the switched-capacitor circuit 20. The output terminal 111 is connected to the node N4 of the switched-capacitor circuit 20.

The output terminal 112 is an output terminal for the voltage V3. Specifically, the output terminal 112 is a terminal for supplying the voltage V3 to the switched-capacitor circuit 20. The output terminal 112 is connected to the node N3 of the switched-capacitor circuit 20.

The output terminal 113 is an output terminal for the voltage V2. Specifically, the output terminal 113 is a terminal for supplying the voltage V2 to the switched-capacitor circuit 20. The output terminal 113 is connected to the node N2 of the switched-capacitor circuit 20.

The output terminal 114 is an output terminal for the voltage V1. Specifically, the output terminal 114 is a terminal for supplying the voltage V1 to the switched-capacitor circuit 20. The output terminal 114 is connected to the node N1 of the switched-capacitor circuit 20.

The inductor connection terminal 115 is connected to one end of the power inductor L71. The inductor connection terminal 116 is connected to the other end of the power inductor L71.

The switch S71 is connected between the input terminal 110 and the one end of the power inductor L71. Specifically, the switch S71 has a terminal connected to the input terminal 110, and a terminal connected to the one end of the power inductor L71 via the inductor connection terminal 115. In this connection configuration, ON/OFF switching of the switch S71 based on a control signal S1 enables switching between connection and disconnection between the input terminal 110 and the one end of the power inductor L71.

The switch S72 is connected between the one end of the power inductor L71 and ground. Specifically, the switch S72 has a terminal connected to the one end of the power inductor L71 via the inductor connection terminal 115, and a terminal connected to ground. In this connection configuration, ON/OFF switching of the switch S72 based on the control signal S1 enables switching between connection and disconnection between the one end of the power inductor L71 and ground.

The switch S61 is connected between the other end of the power inductor L71 and the output terminal 111. Specifically, the switch S61 has a terminal connected to the other end of the power inductor L71 via the inductor connection terminal 116, and a terminal connected to the output terminal 111. In this connection configuration, ON/OFF switching of the switch S61 based on the control signal S1 enables switching between connection and disconnection between the other end of the power inductor L71 and the output terminal 111.

The switch S62 is connected between the other end of the power inductor L71 and the output terminal 112. Specifically, the switch S62 has a terminal connected to the other end of the power inductor L71 via the inductor connection terminal 116, and a terminal connected to the output terminal 112. In this connection configuration, ON/OFF switching of the switch S62 based on the control signal S1 enables switching between connection and disconnection between the other end of the power inductor L71 and the output terminal 112.

The switch S63 is connected between the other end of the power inductor L71 and the output terminal 113. Specifically, the switch S63 has a terminal connected to the other end of the power inductor L71 via the inductor connection terminal 116, and a terminal connected to the output terminal 113. In this connection configuration, ON/OFF switching of the switch S63 based on the control signal S1 enables switching between connection and disconnection between the other end of the power inductor L71 and the output terminal 113.

The switches S71 and S72 are at least one switch included in the converter circuit 10.

One of the two electrodes of the capacitor C61 is connected to the switch S61 and the output terminal 111. The other of the two electrodes of the capacitor C61 is connected to the switch S62, the output terminal 112, and one of the two electrodes of the capacitor C62. The capacitor C61 functions as a smoothing capacitor.

The one of the two electrodes of the capacitor C62 is connected to the switch S62, the output terminal 112, and the other of the two electrodes of the capacitor C61. The other of the two electrodes of the capacitor C62 is connected to a path connecting the switch S63, the output terminal 113, and one of the two electrodes of the capacitor C63.

The one of the two electrodes of the capacitor C63 is connected to the switch S63, the output terminal 113, and the other of the two electrodes of the capacitor C62. The other of the two electrodes of the capacitor C63 is connected to the output terminal 114 and one of the two electrodes of the capacitor C64.

The one of the two electrodes of the capacitor C64 is connected to the output terminal 114 and the other of the two electrodes of the capacitor C63. The other of the two electrodes of the capacitor C64 is connected to ground.

The switches S61 to S63 are controlled so as to be exclusively turned ON. In other words, only any one of the switches S61 to S63 is turned ON, and the others are turned OFF. Turning ON of only any one of the switches S61 to S63 enables the converter circuit 10 to change the voltage to be supplied to the switched-capacitor circuit 20 at the voltage levels of the voltages V2 to V4.

The converter circuit 10 configured as described above for supplying electric charges to the switched-capacitor circuit 20 via at least one of the output terminals 111 to 113.

In an exemplary aspect, when an input voltage is converted into one first voltage, it is sufficient that the converter circuit 10 include at least the switches S71 and S72 and the power inductor L71.

### [2.4 Circuit Configuration of Filter Circuit 40]

The filter circuit 40 can attenuate noise from a plurality of discrete voltages supplied to the PA 50. The filter circuit 40 is also sometimes called a pulse shaping filter or a transition shaping filter.

As illustrated in FIG. 7, the filter circuit 40 includes inductors L1 and L2, a capacitor C1, an input terminal 140, and an output terminal 141.

The input terminal 140 is connected to the output terminal 130 of the supply modulator 30. The input terminal 140 is a terminal for receiving a voltage selected from among the plurality of discrete voltages by the supply modulator 30.

The output terminal 141 is an external connection terminal of the tracker circuit 2, and is connected to the PA 50 outside the tracker circuit 2. The output terminal 141 is a terminal for supplying a plurality of discrete voltages passing through the filter circuit 40 to the PA 50.

The inductor L1 is connected between the input terminal 140 and the output terminal 141. In other words, the inductor L1 is disposed in series with a path connecting the input terminal 140 and the output terminal 141. Specifically, one end of the inductor L1 is connected to the input terminal 140, and the other end of the inductor L1 is connected to the output terminal 141.

The inductor L2 is connected between a path connecting the inductor L1 and the output terminal 141 and ground. In other words, the inductor L2 is shunt connected to the path connecting the input terminal 140 and the output terminal 141. Specifically, one end of the inductor L2 is connected to the node N41 on the path connecting the inductor L1 and the output terminal 141, and the other end of the inductor L2 is connected to ground via the capacitor C1. The inductor L2 may be connected between the capacitor C1 and ground, and may be omitted from the filter circuit 40 in an alternative exemplary aspect.

The capacitor C1 is connected between the inductor L2 and ground. In other words, the capacitor C1 is shunt connected to the path connecting the input terminal 140 and the output terminal 141. Specifically, one end of the capacitor C1 is connected to the inductor L2, and the other end of the capacitor C1 is connected to ground.

The filter circuit 40 may include a switch SW1 disposed in series with a path bypassing the inductor L1 between the input terminal 140 and the output terminal 141. This allows the filter circuit 40 to switch ON/OFF a band elimination filter for eliminating noise from a plurality of discrete voltages.

Such ON/OFF of the band elimination filter can be controlled based on a channel band width (that is, modulation band width) of a radio frequency (RF) signal RFA, for example. In an exemplary aspect, when the PA 50 is configured to amplify transmission signals of a plurality of frequency bands, ON/OFF of the switch SW1 may be controlled based on the frequency band of the transmission signal amplified by the PA 50. It is noted that the control of the band elimination filter is not limited to the above. For example, a circuit element other than the inductor L1 may be inserted into the path connecting the input terminal 140 and the output terminal 141 in an exemplary aspect.

The tracker circuit 2 may include a digital control circuit that processes a source-synchronous digital control signal received from the BBIC 300 to generate the control signals S1, S2, and S4. The control signal S1 is a signal for controlling ON/OFF of the switches S61 to S63, S71, and S72 included in the converter circuit 10. The control signal S2 is a signal for controlling ON/OFF of the switches S11 to S14, S21 to S24, S31 to S34, and S41 to S44 included in the switched-capacitor circuit 20. The control signal S4 is a signal for controlling ON/OFF of the switch SW1 included in the filter circuit 40.

The tracker circuit 2 may also include a digital control circuit that processes a digital control logic/line (DCL) signal received from the BBIC 300 to generate the control signal S3. The DCL signal is generated by the BBIC 300 based on an envelope signal of an RF signal or the like. The control signal S3 is a signal for controlling ON/OFF of the switches S51 to S54 included in the supply modulator 30.

### 3. Implementation Example of Radio Frequency Module 1A According to Example 1

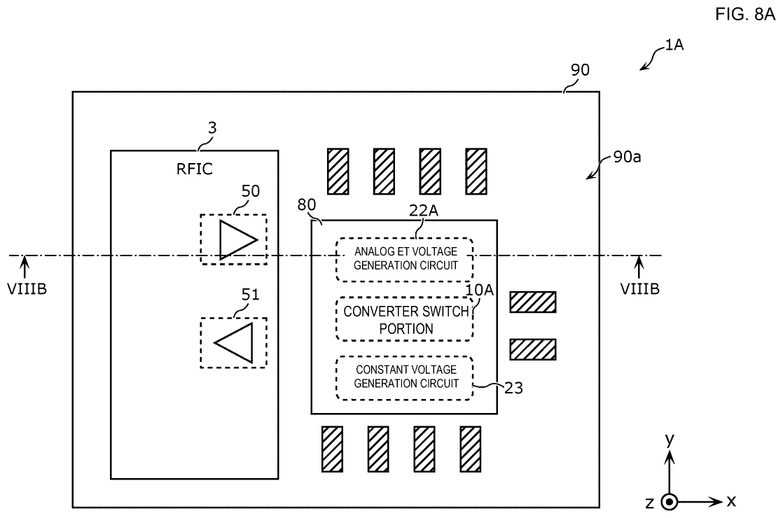

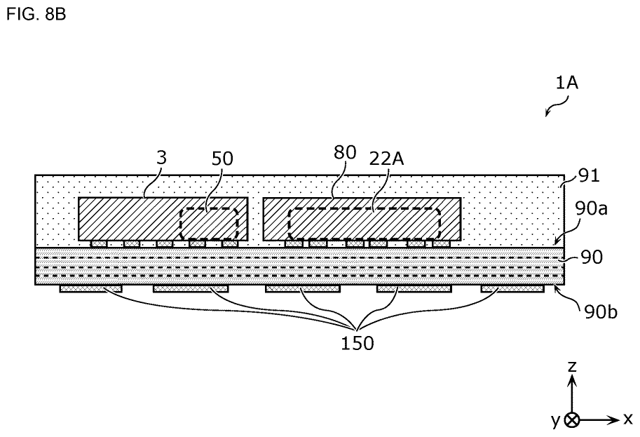

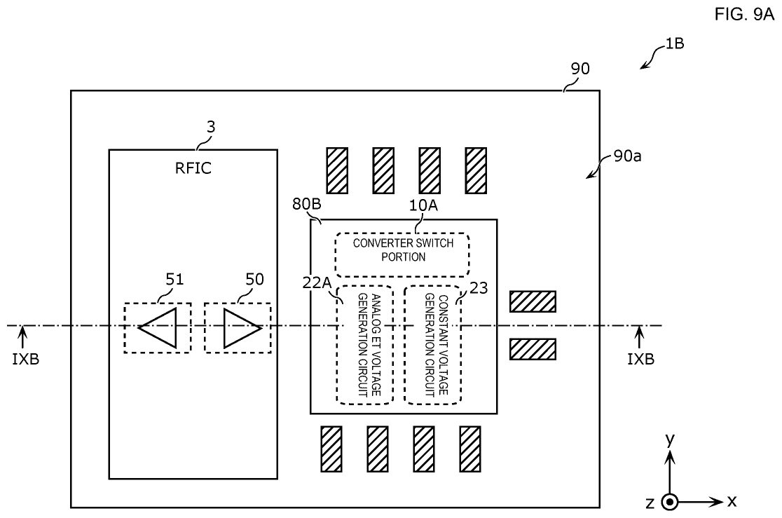

Next, as an implementation example of the radio frequency module 1 configured as described above, a radio frequency module 1A according to Example 1 will be described with reference to FIGS. 8A and 8B.

FIG. 8A is a plan view of the radio frequency module 1A according to Example 1. FIG. 8B is a cross-sectional view of the radio frequency module 1A according to Example 1. FIG. 8A illustrates a main surface 90a of a module laminate 90 viewed from the z-axis positive side. FIG. 8B illustrates a cross-section taken along line VIIIB-VIIIB in FIG. 8A.

In FIGS. 8A and 8B, some of the wiring connecting a plurality of circuit components disposed on the module laminate 90 is omitted. In FIGS. 8A and 8B, a shield electrode layer that covers the surface of a resin member 91 is omitted. It is noted that the resin member 91 and the shield electrode layer may be omitted according to alternative exemplary aspects. Moreover, in FIG. 8A, the hatched blocks represent optional circuit components that may be omitted in alternative exemplary aspects of the present disclosure.

As illustrated in FIG. 8A, the radio frequency module 1A includes the module laminate 90, an RFIC 3, and an integrated circuit 80.

The module laminate 90 has the main surface 90a (first main surface) and a main surface 90b (second main surface) that face each other. A ground plane and the like are formed in the module laminate 90 and on the main surface 90a. In FIG. 8A, the module laminate 90 has a rectangular shape in plan view, but the shape of the module laminate 90 is not limited thereto.

For example, the module laminate 90 may be, but is not limited to, a low temperature co-fired ceramics (LTCC) substrate or a high temperature co-fired ceramics (HTCC) substrate having a multilayer structure of a plurality of dielectric layers, a component-embedded board, a substrate having a redistribution layer (RDL), or a printed circuit board.

The resin member 91 is disposed on the main surface 90a, covers the main surface 90a and some of the plurality of circuit components, and has a function to ensure the reliability of the plurality of circuit components, such as mechanical strength and moisture resistance.

The integrated circuit 80 is an example of a first integrated circuit, and is at least one integrated circuit included in the tracker circuit 2.

The tracker circuit 2 in this example includes a converter circuit 10, an analog ET voltage generation circuit 22A, and a constant voltage generation circuit 23.

The integrated circuit 80 is disposed on the main surface 90a of the module laminate 90, and includes a converter switch portion 10A, the analog ET voltage generation circuit 22A, and the constant voltage generation circuit 23. The converter switch portion 10A includes switches S71 and S72 of the converter circuit 10. It is sufficient that the integrated circuit 80 include the converter switch portion 10A, and the integrated circuit 80 does not have to include the analog ET voltage generation circuit 22A or the constant voltage generation circuit 23 in an alternative exemplary aspect.

In FIG. 8A, the integrated circuit 80 has a rectangular shape in plan view of the module laminate 90, but the shape of the integrated circuit 80 is not limited thereto.

The integrated circuit 80 is configured using, for example, a complementary metal oxide semiconductor (CMOS), and specifically may be manufactured by a silicon on insulator (SOI) process. The integrated circuit 80 is not limited to the CMOS.

The RFIC 3 is an example of a second integrated circuit, and is a signal processing circuit configured to output a radio frequency signal to an antenna 200. The RFIC 3 includes a first amplifying transistor of a power amplifier (PA) 50 and a second amplifying transistor of a low-noise amplifier 51. The RFIC 3 is disposed on the main surface 90a of the module laminate 90.

It is noted that the RFIC 3 according to this example can omit the PA 50 or the low-noise amplifier 51. In this case, the amplifier circuit including the PA 50 and the low-noise amplifier 51 corresponds to the second integrated circuit, and this amplifier circuit is disposed on the main surface 90a.

According to the above configuration, the second integrated circuit (RFIC 3) includes the first amplifying transistor of the PA 50 and the second amplifying transistor of the low-noise amplifier 51. The first integrated circuit (integrated circuit 80) includes a circuit configured to supply a variable voltage to the PA 50 and a circuit configured to supply a constant voltage to the low-noise amplifier 51. The first integrated circuit and the second integrated circuit are disposed on the single module laminate 90. Thus, the radio frequency module 1A can be reduced in size. Accordingly, this configuration provides a small radio frequency module 1A and a small communication device 4 having an ET mode power amplifier system.

As illustrated in FIGS. 8A and 8B, the RFIC 3 and the integrated circuit 80 are disposed adjacent to each other on the main surface 90a.

Thus, the radio frequency module 1A can be further reduced in size.

The PA 50 and the low-noise amplifier 51 are disposed adjacent to the integrated circuit 80 on the main surface 90a.

Accordingly, wiring for supplying a variable voltage from the tracker circuit 2 to the PA 50 can be shortened. Thus, ringing of the variable voltage and similar effects can be reduced, and the variable voltage can be stabilized. Wiring for supplying a constant voltage from the tracker circuit 2 to the low-noise amplifier 51 can also be shortened. Thus, the inflow of noise into the wiring can be reduced, and deterioration of receiving sensitivity of the low-noise amplifier 51 can be reduced.

### 4. Implementation Example of Radio Frequency Module 1B According to Example 2

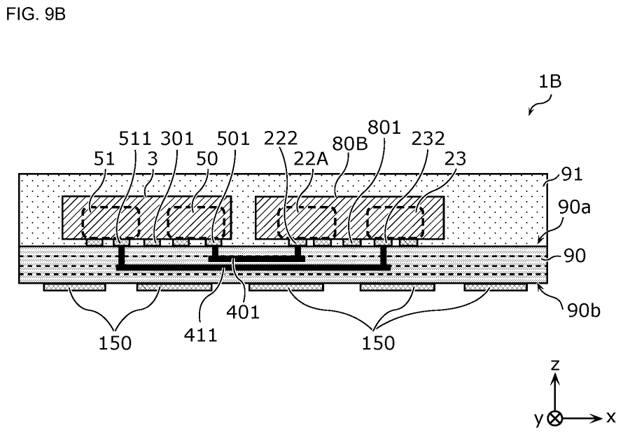

FIG. 9A is a plan view of a radio frequency module 1B according to Example 2. FIG. 9B is a cross-sectional view of the radio frequency module 1B according to Example 2. FIG. 9A illustrates a main surface 90a of a module laminate 90 viewed from the z-axis positive side. FIG. 9B illustrates a cross-section taken along line IXB-IXB in FIG. 9A.

As illustrated in FIG. 9A, the radio frequency module 1B includes the module laminate 90, an RFIC 3, and an integrated circuit 80B. The radio frequency module 1B according to this example differs from the radio frequency module 1A according to Example 1 in the arrangement configuration of a power amplifier (PA) 50 and a low-noise amplifier 51 in the RFIC 3 and also in the arrangement configuration of a converter switch portion 10A, an analog ET voltage generation circuit 22A, and a constant voltage generation circuit 23 in the integrated circuit 80B. Hereinafter, regarding the radio frequency module 1B according to this example, descriptions of the same points as those of the radio frequency module 1A according to Example 1 will be omitted, and differences will be mainly described.

The integrated circuit 80B is an example of a first integrated circuit, and is at least one integrated circuit included in the tracker circuit 2.

The tracker circuit 2 in this example includes a converter circuit 10, the analog ET voltage generation circuit 22A, and the constant voltage generation circuit 23.

The integrated circuit 80B is disposed on the main surface 90a of the module laminate 90, and includes the converter switch portion 10A, the analog ET voltage generation circuit 22A, and the constant voltage generation circuit 23. The converter switch portion 10A includes switches S71 and S72 of the converter circuit 10. It is sufficient that the integrated circuit 80B include the converter switch portion 10A, and the integrated circuit 80B may omit the analog ET voltage generation circuit 22A or the constant voltage generation circuit 23 in an alternative exemplary aspect.

According to the above configuration, a second integrated circuit (RFIC 3) includes a first amplifying transistor of the PA 50 and a second amplifying transistor of the low-noise amplifier 51. The first integrated circuit (integrated circuit 80B) includes a circuit for supplying a variable voltage to the PA 50 and a circuit for supplying a constant voltage to the low-noise amplifier 51. The first integrated circuit and the second integrated circuit are disposed on one module laminate. Thus, the radio frequency module 1B can be reduced in size.

As illustrated in FIG. 9B, the integrated circuit 80B has an output terminal 222 (first output terminal) for outputting a variable voltage from the analog ET voltage generation circuit 22A, and an output terminal 232 (second output terminal) for outputting a constant voltage from the constant voltage generation circuit 23. The RFIC 3 also has an input terminal 501 (first input terminal) connected to the PA 50 and the output terminal 222, and an input terminal 511 (second input terminal) connected to the low-noise amplifier 51 and the output terminal 232.

Here, as illustrated in FIG. 9B, a distance between the output terminal 222 and the input terminal 501 is smaller than a distance between the output terminal 232 and the input terminal 511.

Accordingly, wiring 401 for supplying the variable voltage from the tracker circuit 2 to the PA 50 can be preferentially shortened. Thus, ringing of the variable voltage and similar effects can be reduced, and the variable voltage can be stabilized.

As illustrated in FIG. 9B, at least one terminal 801 is disposed between the output terminal 222 and the output terminal 232. Accordingly, intrusion of noise generated at the output terminal 222 into the output terminal 232 can be reduced, and deterioration of receiving sensitivity can be reduced.

As illustrated in FIG. 9B, at least one terminal 301 is disposed between the input terminal 501 and the input terminal 511. Accordingly, intrusion of noise generated at the input terminal 501 into the input terminal 511 can be reduced, and deterioration of receiving sensitivity can be reduced.

### 5. Implementation Example of Radio Frequency Module 1C According to Example 3

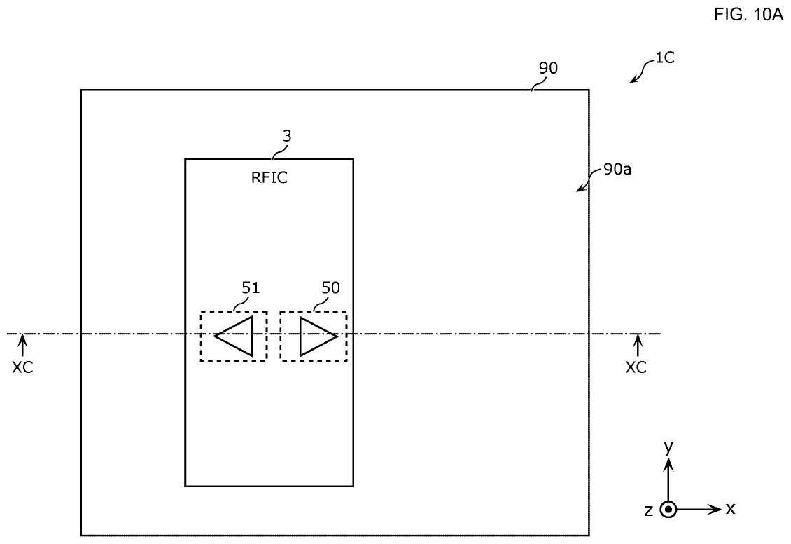

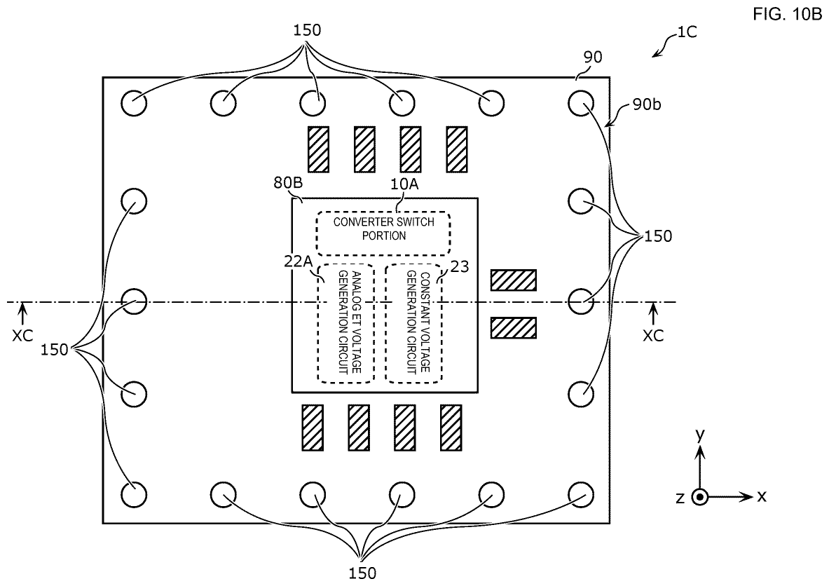

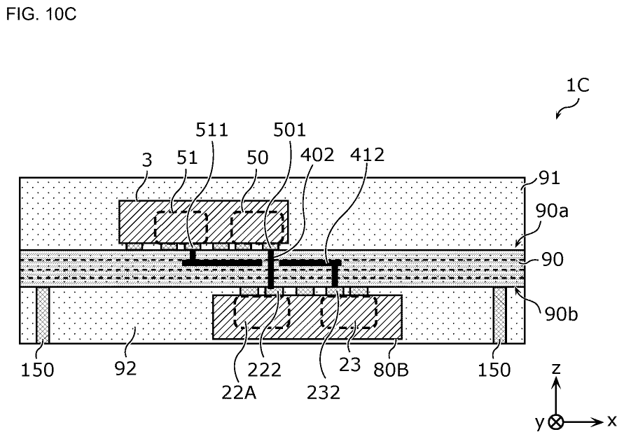

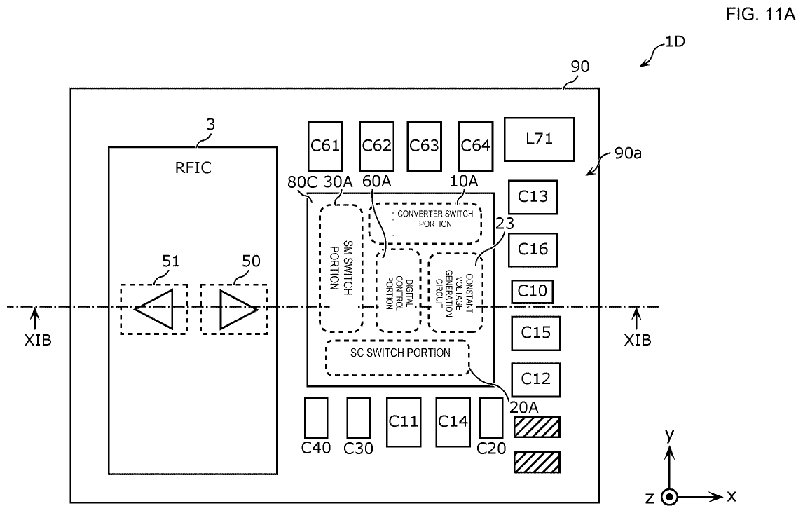

FIGS. 10A and 10B are plan views of a radio frequency module 1C according to Example 3. FIG. 10C is a cross-sectional view of the radio frequency module 1C according to Example 3. FIG. 10A illustrates a main surface 90a of a module laminate 90 viewed from the z-axis positive side. FIG. 10B is a transparent view of a main surface 90b of the module laminate 90 viewed from the z-axis positive side. FIG. 10C illustrates a cross-section taken along line XC-XC in FIGS. 10A and 10B.

As illustrated in FIGS. 10A and 10B, the radio frequency module 1C includes the module laminate 90, an RFIC 3, and an integrated circuit 80B. The radio frequency module 1C according to this example differs from the radio frequency module 1B according to Example 2 in that the RFIC 3 and the integrated circuit 80B are disposed separately on both sides. Hereinafter, regarding the radio frequency module 1C according to this example, descriptions of the same points as those of the radio frequency module 1B according to Example 2 will be omitted, and differences will be mainly described.

A resin member 91 is disposed on the main surface 90a, covers the main surface 90a and some of a plurality of circuit components, and has a function to ensure reliability of the plurality of circuit components, such as mechanical strength and moisture resistance. A resin member 92 is disposed on the main surface 90b, covers the main surface 90b and some of the plurality of circuit components, and has a function to ensure reliability of the plurality of circuit components, such as mechanical strength and moisture resistance.

As illustrated in FIGS. 10A to 10C, the RFIC 3 is disposed on the main surface 90a, and the integrated circuit 80B is disposed on the main surface 90b.

Accordingly, the second integrated circuit (RFIC 3) and the integrated circuit 80B are disposed on the main surfaces 90a and 90b, respectively, and thus the radio frequency module 1C can be reduced in size.

As illustrated in FIG. 10C, in plan view of the module laminate 90, the RFIC 3 and the integrated circuit 80B at least partially overlap.

Accordingly, the radio frequency module 1C can be further reduced in size.

In plan view of the module laminate 90, a power amplifier (PA) 50 and the integrated circuit 80B at least partially overlap.

Accordingly, wiring 402 for supplying a variable voltage from the tracker circuit 2 to the PA 50 can be shortened. Thus, ringing of the variable voltage and similar effects can be reduced, and the variable voltage can be stabilized.

As illustrated in FIG. 10C, in plan view of the module laminate 90, the RFIC 3 and an output terminal 222 at least partially overlap, and the RFIC 3 and an output terminal 232 do not overlap.

Accordingly, the wiring 402 for supplying the variable voltage from the tracker circuit 2 to the PA 50 can be preferentially shortened. Thus, ringing of the variable voltage and similar effects can be reduced, and the variable voltage can be stabilized. The intrusion of noise generated at an input terminal 501 into the output terminal 232 can also be reduced, and deterioration of receiving sensitivity can be reduced.

In this example, the RFIC 3 may be disposed on the main surface 90b, and the integrated circuit 80B may be disposed on the main surface 90a.

Accordingly, the second integrated circuit (RFIC 3) and the integrated circuit 80B are disposed separately on the main surfaces 90b and 90a. Thus, the radio frequency module 1C can be reduced in size.

### 6. Implementation Example of Radio Frequency Module 1D According to Example 4

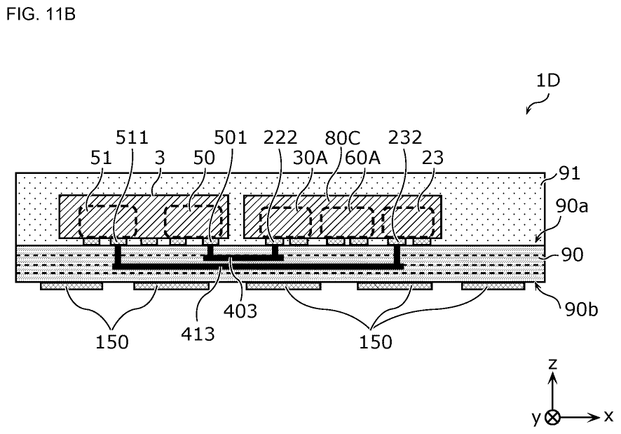

FIG. 11A is a plan view of a radio frequency module 1D according to Example 4. FIG. 11B is a cross-sectional view of the radio frequency module 1D according to Example 4. FIG. 11A illustrates a main surface 90a of a module laminate 90 viewed from the z-axis positive side. FIG. 11B illustrates a cross-section taken along line XIB-XIB in FIG. 11A.

In FIGS. 11A and 11B, some of the wiring connecting a plurality of circuit components disposed on the module laminate 90 is omitted. In FIGS. 11A and 11B, a shield electrode layer that covers the surface of a resin member 91 is omitted. The resin member 91 and the shield electrode layer may be omitted according to alternative exemplary aspects. Moreover, in FIG. 11A, the hatched blocks represent optional circuit components that may be omitted according to alternative exemplary aspects of the present disclosure.

As illustrated in FIG. 11A, the radio frequency module 1D includes the module laminate 90, an RFIC 3, and an integrated circuit 80C.

The module laminate 90 has the main surface 90a (first main surface) and a main surface 90b (second main surface) that face each other. A ground plane and the like are formed in the module laminate 90 and on the main surface 90a. In FIG. 11A, the module laminate 90 has a rectangular shape in plan view, but the shape of the module laminate 90 is not limited thereto.

For example, the module laminate 90 may be, but is not limited to, an LTCC substrate or an HTCC substrate having a multilayer structure of a plurality of dielectric layers, a component-embedded board, a substrate having an RDL, or a printed circuit board.

The resin member 91 is disposed on the main surface 90a, covers the main surface 90a and some of the plurality of circuit components, and has a function to ensure the reliability of the plurality of circuit components, such as mechanical strength and moisture resistance.

The integrated circuit 80C is an example of a first integrated circuit, and is at least one integrated circuit included in the tracker circuit 2.

The tracker circuit 2 according to this example includes a converter circuit 10, a digital ET voltage generation circuit 22B, and a constant voltage generation circuit 23.

The integrated circuit 80C is disposed on the main surface 90a of the module laminate 90, and includes a converter switch portion 10A, an SC switch portion 20A, an SM switch portion 30A, a digital control portion 60A, and the constant voltage generation circuit 23. The converter switch portion 10A includes switches S61 to S63, S71, and S72 of a converter circuit 10. The SC switch portion 20A includes switches S11 to S14, S21 to S24, S31 to S34, and S41 to S44 of a switched-capacitor circuit 20. The SM switch portion 30A includes switches S51 to S54 of a supply modulator 30. The digital control portion 60A includes a digital control circuit.

It is sufficient that the integrated circuit 80C include the converter switch portion 10A, and the integrated circuit 80C may omit the SC switch portion 20A, the SM switch portion 30A, the digital control portion 60A, or the constant voltage generation circuit 23.

In FIG. 11A, the integrated circuit 80C has a rectangular shape in plan view of the module laminate 90, but the shape of the integrated circuit 80C is not limited thereto.

The integrated circuit 80C is configured using, for example, a CMOS, and specifically may be manufactured by an SOI process. The integrated circuit 80C is not limited to the CMOS.

The RFIC 3 is an example of a second integrated circuit, and is a signal processing circuit configured to output a radio frequency signal to an antenna 200. The RFIC 3 includes a first amplifying transistor of a power amplifier (PA) 50 and a second amplifying transistor of a low-noise amplifier 51. The RFIC 3 is disposed on the main surface 90a of the module laminate 90.

It is noted that the RFIC 3 according to this example may omit the PA 50 or the low-noise amplifier 51. In this case, an amplifier circuit including the PA 50 and the low-noise amplifier 51 corresponds to the second integrated circuit, and the amplifier circuit is disposed on the main surface 90a.

With the above configuration, the second integrated circuit (RFIC 3) includes the first amplifying transistor of the PA 50 and the second amplifying transistor of the low-noise amplifier 51. The first integrated circuit (integrated circuit 80C) includes a circuit configured to supply a plurality of discrete voltages (variable voltages) to the PA 50 and a circuit configured to supply a constant voltage to the low-noise amplifier 51. The first integrated circuit and the second integrated circuit are disposed on the single module laminate 90. Thus, the radio frequency module 1D can be reduced in size. Accordingly, this configuration provides a small radio frequency module 1D and a small communication device 4 having an ET mode power amplifier system.

As illustrated in FIGS. 11A and 11B, the RFIC 3 and the integrated circuit 80C are disposed adjacent to each other on the main surface 90a.

Thus, the radio frequency module 1D can be further reduced in size.

The PA 50 and the integrated circuit 80C are disposed adjacent to each other on the main surface 90a.

Accordingly, wiring 403 for supplying a plurality of discrete voltages from the tracker circuit 2 to the PA 50 can be shortened. Thus, waveform rounding of the plurality of discrete voltages, and the like can be reduced, and the plurality of discrete voltages can be stabilized.

The integrated circuit 80C has an output terminal 222 (first output terminal) for outputting a plurality of discrete voltages from the digital ET voltage generation circuit 22B (SM switch portion 30A), and an output terminal 232 (second output terminal) for outputting a constant voltage from the constant voltage generation circuit 23. The RFIC 3 has an input terminal 501 (first input terminal) connected to the PA 50 and the output terminal 222, and an input terminal 511 (second input terminal) connected to the low-noise amplifier 51 and the output terminal 232.

Here, as illustrated in FIG. 11B, a distance between the output terminal 222 and the input terminal 501 is smaller than a distance between the output terminal 232 and the input terminal 511.

Accordingly, the wiring 403 for supplying a plurality of discrete voltages from the tracker circuit 2 to the PA 50 can be preferentially shortened. Thus, waveform rounding of the plurality of discrete voltages, and the like can be reduced, and the plurality of discrete voltages can be stabilized.

As illustrated in FIG. 11B, at least one terminal is disposed between the output terminal 222 and the output terminal 232. Accordingly, intrusion of noise generated at the output terminal 222 into the output terminal 232 can be reduced, and deterioration of receiving sensitivity can be reduced.

As illustrated in FIG. 11B, at least one terminal is disposed between the input terminal 501 and the input terminal 511. Accordingly, intrusion of noise generated at the input terminal 501 into the input terminal 511 can be reduced, and the deterioration of receiving sensitivity can be reduced.

As illustrated in FIG. 11A, the SM switch portion 30A and the constant voltage generation circuit 23 are separated in the integrated circuit 80C in this exemplary aspect. Specifically, the digital control portion 60A is interposed between the SM switch portion 30A and the constant voltage generation circuit 23.

Accordingly, intrusion of noise caused by the plurality of discrete voltages outputted from the SM switch portion 30A into the constant voltage generation circuit 23 can be reduced, and the deterioration of receiving sensitivity can be reduced.

The radio frequency module 1D further includes capacitors C61 to C64 and a power inductor L71 included in the converter circuit 10, and capacitors C11 to C16 and capacitors C10 to C40 included in the switched-capacitor circuit 20.

The capacitors C61 to C64 and the power inductor L71, as well as the capacitors C11 to C16 and the capacitors C10 to C40 are disposed on the main surface 90a.

The capacitors C61 to C64, the capacitors C11 to C16, and the capacitors C10 to C40 are each implemented as a chip capacitor. In an exemplary aspect, the chip capacitor can be a surface mount device (SMD) forming a capacitor. The implementation of the plurality of capacitors is not limited to chip capacitors. For example, some or all of the plurality of capacitors may be included in an integrated passive device (IPD), or may be included in the integrated circuit 80C.

In this way, the plurality of capacitors and the inductor disposed on the main surface 90a are grouped for the individual circuits and disposed around the integrated circuit 80C.

Specifically, a group of the capacitors C61 to C64 and the power inductor L71 included in the converter circuit 10 is disposed in a region on the main surface 90a sandwiched between a straight line along the upper side of the integrated circuit 80C and a straight line along the upper side of the module laminate 90 in plan view of the module laminate 90. Accordingly, a group of the circuit components included in the converter circuit 10 is disposed near the converter switch portion 10A disposed in the upper part of the integrated circuit 80C.

A group of the capacitors C11 to C16 and the capacitors C10 to C40 included in the switched-capacitor circuit 20 is disposed in a region on the main surface 90a sandwiched between a straight line along the right side of the integrated circuit 80C and a straight line along the right side of the module laminate 90, and a region on the main surface 90a sandwiched between a straight line along the lower side of the integrated circuit 80C and a straight line along the lower side of the module laminate 90, in plan view of the module laminate 90. Accordingly, a group of the circuit components included in the switched-capacitor circuit 20 is disposed near the SC switch portion 20A disposed in the lower part of the integrated circuit 80C.

Accordingly, wiring loss in the converter circuit 10 and the switched-capacitor circuit 20 can be reduced, and power consumption can be reduced.

### 7. Implementation Example of Radio Frequency Module 1E According to Example 5

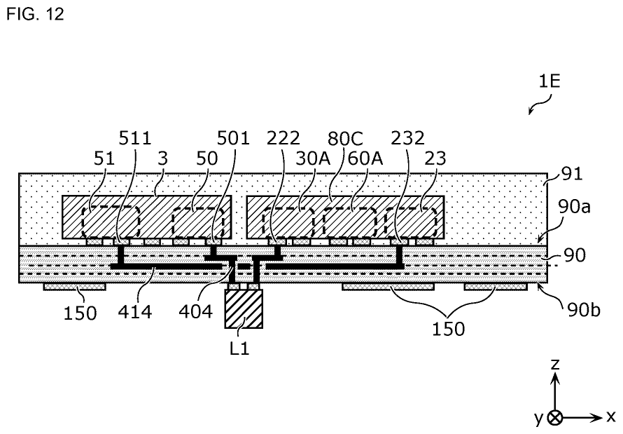

FIG. 12 is a cross-sectional view of a radio frequency module 1E according to Example 5.

As illustrated in FIG. 12, the radio frequency module 1E includes a module laminate 90, an RFIC 3, an integrated circuit 80C, and a filter circuit 40 (only an inductor L1 is illustrated in FIG. 12). The radio frequency module 1E according to this example differs from the radio frequency module 1D according to Example 4 in including the filter circuit 40. Hereinafter, regarding the radio frequency module 1E according to this example, descriptions of the same points as those of the radio frequency module 1D according to Example 4 will be omitted, and differences will be mainly described.

The radio frequency module 1E further includes the filter circuit 40 connected between a supply modulator 30 and a power amplifier (PA) 50. The filter circuit 40 is configured to attenuate noise from a plurality of discrete voltages. As illustrated in FIG. 7, the filter circuit 40 includes inductors L1 and L2 and a capacitor C1, for example.

The capacitor C1 is implemented as a chip capacitor. The implementation of the capacitor C1 is not limited to a chip capacitor. For example, the capacitor C1 may be included in an IPD.

The inductors L1 and L2 are each mounted as chip inductors. In an exemplary aspect, the chip inductor can be an SMD forming an inductor. The implementation of the inductors L1 and L2 is not limited to chip inductors. For example, some or all of the inductors L1 and L2 may be included in an IPD.

The inductors L1 and L2, and the capacitor C1 are disposed on the main surface 90b.

With the above configuration, the PA 50 and the integrated circuit 80C are disposed adjacent to each other on the main surface 90a, and the filter circuit 40 is disposed on the main surface 90b. Accordingly, this configuration enables noise from a plurality of discrete voltages supplied to the PA 50 to be attenuated. Thus, the radio frequency module 1E can be reduced in size.

As illustrated in FIG. 12, in plan view of the module laminate 90, at least one of the RFIC 3 and the integrated circuit 80C and the filter circuit 40 may at least partially overlap.

Accordingly, wiring 404 connecting the supply modulator 30 and the PA 50 via the filter circuit 40 can be shortened. Thus, a plurality of discrete voltages from the tracker circuit 2 to the PA 50 can be stabilized.

A plurality of external connection terminals 150 are disposed on the main surface 90b. The plurality of external connection terminals 150 are electrically connected to a plurality of electronic components disposed on the main surface 90a and to the filter circuit disposed on the main surface 90b through via conductors or the like formed in the module laminate 90. The plurality of external connection terminals 150 may be, but are not limited to, bump electrodes and planar electrodes. For example, the plurality of external connection terminals 150 may be solder electrodes.

The filter circuit 40 may be disposed between the RFIC 3 and the integrated circuit 80C on the main surface 90a.

Accordingly, wiring connecting the supply modulator 30 and the PA 50 via the filter circuit 40 can be shortened. Thus, a plurality of discrete voltages from the tracker circuit 2 to the PA 50 can be stabilized.

### 8. Implementation Example of Radio Frequency Module 1F According to Example 6

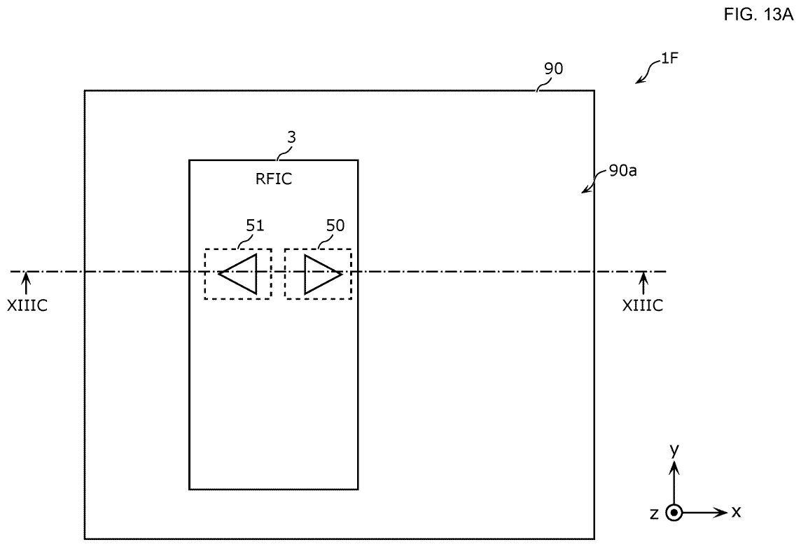

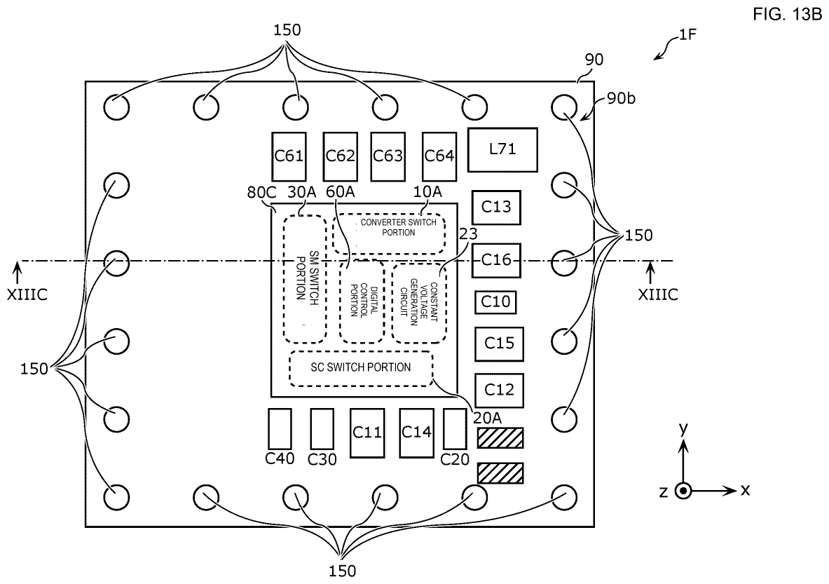

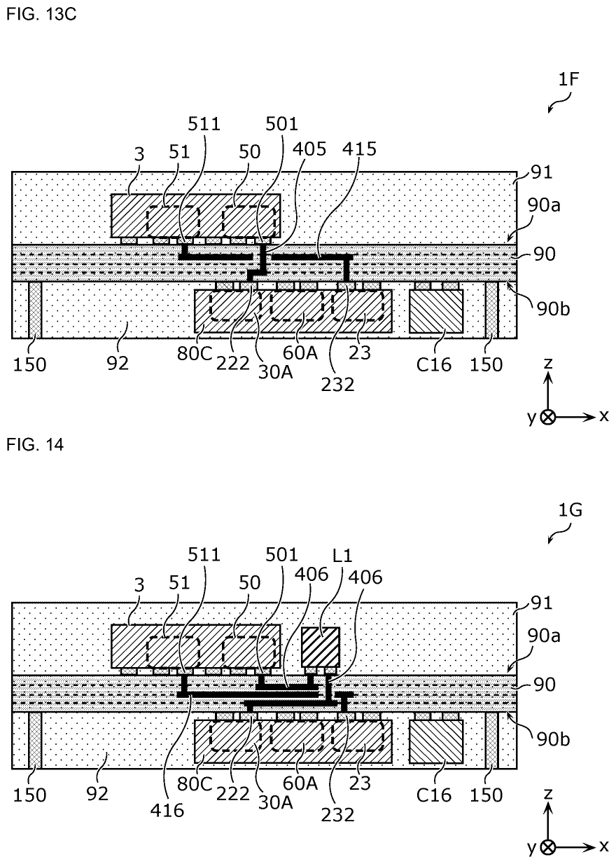

FIGS. 13A and 13B are plan views of a radio frequency module 1F according to Example 6. FIG. 13C is a cross-sectional view of the radio frequency module 1F according to Example 6. FIG. 13A illustrates a main surface 90a of a module laminate 90 viewed from the z-axis positive side. FIG. 13B is a transparent view of a main surface 90b of the module laminate 90 viewed from the z-axis positive side. FIG. 13C illustrates a cross-section taken along line XIIIC-XIIIC in FIGS. 13A and 13B.

As illustrated in FIGS. 13A and 13B, the radio frequency module 1F includes the module laminate 90, RFIC 3, and an integrated circuit 80C. The radio frequency module 1F according to this example differs from the radio frequency module 1D according to Example 4 in that the RFIC 3 and the integrated circuit 80C are disposed separately on both sides. Hereinafter, regarding the radio frequency module 1F according to this example, descriptions of the same points as those of the radio frequency module 1D according to Example 4 will be omitted, and differences will be mainly described.

A resin member 91 is disposed on the main surface 90a, covers the main surface 90a and some of a plurality of circuit components, and has a function to ensure reliability of the plurality of circuit components, such as mechanical strength and moisture resistance. The resin member 92 is disposed on the main surface 90b, covers the main surface 90b and some of the circuit components, and has the function of ensuring the reliability of the circuit components, such as mechanical strength and moisture resistance.

As illustrated in FIGS. 13A to 13C, the RFIC 3 are disposed on the main surface 90a, and the integrated circuit 80C is disposed on the main surface 90b.

Accordingly, the second integrated circuit (RFIC 3) and the integrated circuit 80C are disposed on the main surfaces 90a and 90b, respectively. Thus, the radio frequency module 1F can be reduced in size.

As illustrated in FIG. 13C, in plan view of the module laminate 90, the RFIC 3 and the integrated circuit 80C at least partially overlap.

Accordingly, the radio frequency module 1F can be further reduced in size.

In plan view of the module laminate 90, a power amplifier (PA) 50 and the integrated circuit 80C at least partially overlap.

Accordingly, wiring 405 for supplying a plurality of discrete voltages from the tracker circuit 2 to the PA 50 can be shortened. Thus, waveform rounding of the plurality of discrete voltages, and the like can be reduced, and the plurality of discrete voltages can be stabilized.

As illustrated in FIG. 13C, in plan view of the module laminate 90, the RFIC 3 and an output terminal 222 at least partially overlap, and the RFIC 3 and an output terminal 232 do not overlap.

Accordingly, the wiring 405 for supplying the plurality of discrete voltages from the tracker circuit 2 to the PA 50 can be preferentially shortened. Thus, waveform rounding of the plurality of discrete voltages, and the like can be reduced, and the plurality of discrete voltages can be stabilized. Further, intrusion of noise generated at an input terminal 501 into the output terminal 232 can be reduced, and deterioration of receiving sensitivity can be reduced.

In this example, the RFIC 3 may be disposed on the main surface 90b, and the integrated circuit 80C may be disposed on the main surface 90a.

Accordingly, the second integrated circuit (RFIC 3) and the integrated circuit 80C are disposed separately on the main surfaces 90b and 90a. Thus, the radio frequency module 1F can be reduced in size.

### 9. Implementation Example of Radio Frequency Module 1G According to Example 7

FIG. 14 is a cross-sectional view of a radio frequency module 1G according to Example 7.

As illustrated in FIG. 14, the radio frequency module 1G includes the module laminate 90, RFIC 3, an integrated circuit 80C, and a filter circuit 40 (inductors L1). The radio frequency module 1G according to this example differs in the configuration from the radio frequency module 1F according to Example 6 in including the filter circuit 40. Hereinafter, regarding the radio frequency module 1G according to this example, descriptions of the same points as those of the radio frequency module 1F according to Example 6 will be omitted, and differences will be mainly described.

The radio frequency module 1G further includes the filter circuit 40 connected between a supply modulator 30 and the PA 50. The filter circuit 40 is configured to attenuate noise from a plurality of discrete voltages. As illustrated in FIG. 7, the filter circuit 40 includes inductors L1 and L2 and a capacitor C1, for example.

The capacitor C1 is implemented as a chip capacitor. The implementation of the capacitor C1 is not limited to a chip capacitor. For example, the capacitor C1 may be included in an IPD.

The inductors L1 and L2 are each mounted as chip inductors. In an exemplary aspect, the chip inductor can be an SMD forming an inductor. The implementation of the inductors L1 and L2 is not limited to chip inductors. For example, some or all of the inductors L1 and L2 may be included in an IPD.

The inductors L1 and L2, and the capacitor C1 are disposed on a main surface 90a. The filter circuit 40 and the PA 50 are disposed adjacent to each other.

Accordingly, a second integrated circuit (RFIC 3) and the integrated circuit 80C are disposed separately on the main surface 90a and a main surface 90b. Thus, the radio frequency module 1G can be reduced in size.

Wiring 406 connecting the supply modulator 30 and the PA 50 via the filter circuit 40 can be shortened. Accordingly, this configuration enables noise from a plurality of discrete voltages supplied to the PA 50 to be attenuated. Thus, the plurality of discrete voltages from the tracker circuit 2 to the PA 50 can be stabilized.

In this example, the RFIC 3 may be disposed on the main surface 90b, and the integrated circuit 80C may be disposed on the main surface 90a.

Accordingly, the second integrated circuit (RFIC 3) and the integrated circuit 80C are disposed separately on the main surfaces 90b and 90a. Thus, the radio frequency module 1G can be reduced in size.

### 10. Technical Effects

As described above, the radio frequency modules 1A to 1G according to the examples each include the module laminate 90; and the first integrated circuit and the second integrated circuit disposed on the module laminate 90. The first integrated circuit includes at least one switch included in the converter circuit 10. The second integrated circuit includes the first amplifying transistor of the PA 50 that amplifies a radio frequency signal, and the second amplifying transistor of the low-noise amplifier 51 that amplifies a radio frequency signal. The PA 50 is connected to the ET voltage generation circuit 22 configured to generate a variable voltage based on the output voltage from the converter circuit 10 and the envelope signal. The low-noise amplifier 51 is connected to the constant voltage generation circuit 23 configured to generate a constant voltage based on the output voltage from the converter circuit 10.

With the above configuration, the second integrated circuit includes the first amplifying transistor of the PA 50 and the second amplifying transistor of the low-noise amplifier 51. The first integrated circuit includes a circuit configured to supply a variable voltage to the PA 50 and a circuit configured to supply a constant voltage to the low-noise amplifier 51. The first integrated circuit and the second integrated circuit are disposed on one module laminate. Thus, the radio frequency modules 1A to 1G can be reduced in size. Accordingly, this configuration provides small radio frequency modules 1A to 1G and a small communication device 4 having an ET mode power amplifier system.

In the radio frequency modules 1A to 1G, for example, the constant voltage generation circuit 23 includes the output driver circuit 233 and the operational amplifier circuit 234. The output driver circuit 233 is configured to output a constant voltage lower than the maximum value of the output voltage from the converter circuit 10 to the low-noise amplifier 51, based on the output voltage from the operational amplifier circuit 234. The first integrated circuit further includes the output driver circuit 233.

In the radio frequency modules 1D to 1G, for example, the digital ET voltage generation circuit 22B includes the switched-capacitor circuit 20 and the supply modulator 30. The switched-capacitor circuit 20 is configured to generate a plurality of discrete voltages based on the output voltage from the converter circuit 10, and to output the generated plurality of discrete voltages to the supply modulator 30. The supply modulator 30 is configured to selectively output at least one of the generated plurality of discrete voltages as a variable voltage to the PA 50. The first integrated circuit further includes at least one switch included in the switched-capacitor circuit 20 and at least one switch included in the supply modulator 30.

Accordingly, the second integrated circuit includes the first amplifying transistor of the PA 50 and the second amplifying transistor of the low-noise amplifier 51. The first integrated circuit includes a circuit configured to supply a plurality of discrete voltages (variable voltages) to the PA 50 and a circuit configured to supply a constant voltage to the low-noise amplifier 51. The first integrated circuit and the second integrated circuit are disposed on the single module laminate 90. Thus, the radio frequency modules 1D to 1G can be reduced in size. Accordingly, this configuration provides small radio frequency modules 1D to 1G having an ET mode power amplifier system.

In the radio frequency modules 1D and 1E, for example, the module laminate 90 has the main surfaces 90a and 90b facing each other, and the first integrated circuit and the second integrated circuit are disposed adjacent to each other on the main surface 90a.

Accordingly, the radio frequency modules 1D and 1E can be further reduced in size.

In the radio frequency module 1D, for example, the first integrated circuit has the output terminal 222 for outputting a plurality of discrete voltages (variable voltages) and the output terminal 232 for outputting a constant voltage. The second integrated circuit has the input terminal 501 connected to the PA 50 and the output terminal 222, and the input terminal 511 connected to the low-noise amplifier 51 and the output terminal 232. The distance between the output terminal 222 and the input terminal 501 is smaller than the distance between the output terminal 232 and the input terminal 511.

Accordingly, the wiring 403 for supplying the plurality of discrete voltages from the tracker circuit 2 to the PA 50 can be preferentially shortened. Thus, waveform rounding of the plurality of discrete voltages, and the like can be reduced, and the plurality of discrete voltages can be stabilized.

For example, the radio frequency module 1E further includes the filter circuit 40 connected between the supply modulator 30 and the PA 50 and configured to attenuate noise from a plurality of discrete voltages. The filter circuit 40 is disposed on the main surface 90b.

Accordingly, this configuration enables noise from a plurality of discrete voltages supplied to the PA 50 to be attenuated.

In the radio frequency modules 1F and 1G, for example, the first integrated circuit is disposed on the main surface 90b, and the second integrated circuit is disposed on the main surface 90a.

Accordingly, the second integrated circuit and the first integrated circuit are disposed separately on the main surfaces 90a and 90b. Thus, the radio frequency modules 1F and 1G can be reduced in size.

In the radio frequency modules 1F and 1G, for example, the first integrated circuit and the second integrated circuit at least partially overlap in plan view of the module laminate 90.

Accordingly, the radio frequency modules 1F and 1G can be further reduced in size.

In the radio frequency modules 1F and 1G, for example, the first integrated circuit has the output terminal 222 for outputting a plurality of discrete voltages (variable voltages) and the output terminal 232 for outputting a constant voltage. The second integrated circuit has the input terminal 501 connected to the PA 50 and the output terminal 222, and the input terminal 511 connected to the low-noise amplifier 51 and the output terminal 232. In plan view of the module laminate 90, the second integrated circuit and the output terminal 222 at least partially overlap, and the second integrated circuit and the output terminal 232 do not overlap.

Accordingly, the wiring for supplying a plurality of discrete voltages from the tracker circuit 2 to the PA 50 can be preferentially shortened. Thus, waveform rounding of the plurality of discrete voltages, and the like can be reduced, and the plurality of discrete voltages can be stabilized. Further, intrusion of noise generated at the input terminal 501 into the output terminal 232 can be reduced, and deterioration of receiving sensitivity can be reduced.

For example, the radio frequency module 1G further includes the filter circuit 40 connected between the supply modulator 30 and the PA 50 and configured to attenuate noise from a plurality of discrete voltages. The filter circuit 40 is disposed on the main surface 90a. The filter circuit 40 and the PA 50 are disposed adjacent to each other.

Accordingly, the second integrated circuit and the first integrated circuit are disposed separately on the main surfaces 90a and 90b. Thus, the radio frequency module 1G can be reduced in size. The wiring 406 connecting the supply modulator 30 and the PA 50 via the filter circuit 40 can be shortened. Thus, the plurality of discrete voltages from the tracker circuit 2 to the PA 50 can be stabilized.

In the radio frequency modules 1A to 1C, for example, the analog ET voltage generation circuit 22A includes the linear amplifier circuit 225 and the synthesis circuit 226. The linear amplifier circuit 225 is configured to linearly amplify the envelope signal and output the linearly amplified voltage to the synthesis circuit 226. The synthesis circuit 226 is configured to synthesize the linearly amplified voltage and the output voltage from the converter circuit 10 to generate a variable voltage, and to output the generated variable voltage to the PA 50. The first integrated circuit further includes the linear amplifier circuit 225.

With the above configuration, the second integrated circuit includes the first amplifying transistor of the PA 50 and the second amplifying transistor of the low-noise amplifier 51. The first integrated circuit includes a circuit configured to supply a variable voltage to the PA 50 and a circuit configured to supply a constant voltage to the low-noise amplifier 51. The first integrated circuit and the second integrated circuit are disposed on the single module laminate 90. Thus, the radio frequency modules 1A to 1C can be reduced in size. Accordingly, this configuration provides small radio frequency modules 1A to 1C having an ET mode power amplifier system.

In the radio frequency modules 1A and 1B, for example, the module laminate 90 has the main surfaces 90a and 90b facing each other, and the first integrated circuit and the second integrated circuit are disposed adjacent to each other on the main surface 90a.

Accordingly, the radio frequency modules 1A and 1B can be further reduced in size.

In the radio frequency module 1B, for example, the first integrated circuit has the output terminal 222 for outputting a variable voltage and the output terminal 232 for outputting a constant voltage. The second integrated circuit has the input terminal 501 connected to the PA 50 and the output terminal 222, and the input terminal 511 connected to the low-noise amplifier 51 and the output terminal 232. The distance between the output terminal 222 and the input terminal 501 is smaller than the distance between the output terminal 232 and the input terminal 511.

Accordingly, the wiring 401 for supplying the variable voltage from the tracker circuit 2 to the PA 50 can be preferentially shortened. Thus, ringing of the variable voltage and similar effects can be reduced, and the variable voltage can be stabilized.

In the radio frequency module 1C, for example, the module laminate 90 has the main surfaces 90a and 90b facing each other, the first integrated circuit is disposed on the main surface 90b, and the second integrated circuit is disposed on the main surface 90a.

Accordingly, the second integrated circuit and the first integrated circuit are disposed separately on the main surfaces 90a and 90b. Thus, the radio frequency module 1C can be reduced in size.

In the radio frequency module 1C, for example, the first integrated circuit and the second integrated circuit at least partially overlap in plan view of the module laminate 90.

Accordingly, the radio frequency module 1C can be further reduced in size.

In the radio frequency module 1C, for example, the first integrated circuit has the output terminal 222 for outputting a variable voltage and the output terminal 232 for outputting a constant voltage. The second integrated circuit has the input terminal 501 connected to the PA 50 and the output terminal 222, and the input terminal 511 connected to the low-noise amplifier 51 and the output terminal 232. In plan view of the module laminate 90, the second integrated circuit and the output terminal 222 at least partially overlap, and the second integrated circuit and the output terminal 232 do not overlap.

Accordingly, the wiring 402 for supplying the variable voltage from the tracker circuit 2 to the PA 50 can be preferentially shortened. Thus, ringing of the variable voltage and similar effects can be reduced, and the variable voltage can be stabilized. Further, intrusion of noise generated at the input terminal 501 into the output terminal 232 can be reduced, and deterioration of receiving sensitivity can be reduced.

The radio frequency module 1 according to the embodiment includes the module laminate 90, and the first integrated circuit and the second integrated circuit disposed on the module laminate 90. The first integrated circuit has the output terminal 241 (first output terminal) for outputting a variable voltage and the output terminal 242 (second output terminal) for outputting a constant voltage. The second integrated circuit has the input terminal 501 (first input terminal) connected to the PA 50 that amplifies a radio frequency signal and the input terminal 511 (second input terminal) connected to the low-noise amplifier 51 that amplifies a radio frequency signal. The output terminal 241 is connected to the input terminal 501, and the output terminal 242 is connected to the input terminal 511.

With the above configuration, the first integrated circuit and the second integrated circuit are disposed on the single module laminate 90. Thus, the radio frequency module 1 can be reduced in size. Accordingly, this configuration provides a small radio frequency module 1 having an ET mode power amplifier system.

In the radio frequency modules 1A to 1G, for example, the second integrated circuit is a signal processing circuit (RFIC 3) configured to output a radio frequency signal to an antenna.

Accordingly, the second integrated circuit (RFIC 3) includes the first amplifying transistor of the PA 50 and the second amplifying transistor of the low-noise amplifier 51. The first integrated circuit includes a circuit configured to supply a variable voltage to the PA 50 and a circuit configured to supply a constant voltage to the low-noise amplifier 51. The first integrated circuit and the second integrated circuit are disposed on the single module laminate 90. Thus, the radio frequency modules 1A to 1G can be reduced in size. Accordingly, this configuration provides small radio frequency modules 1A to 1G having an ET mode power amplifier system.

In the radio frequency modules 1A to 1G, for example, the PA 50 and the low-noise amplifier 51 are configured to amplify signals in the millimeter wave band or the sub-terahertz band.

For example, the communication device 4 includes the motherboard, the antenna 200 disposed on the motherboard, and any one of the radio frequency modules 1A to 1G disposed on the motherboard and configured to transmit a radio frequency signal to the antenna.

Accordingly, the communication device 4 can realize the effects of the radio frequency modules 1A to 1G.

### Additional Exemplary Embodiments

It is noted that the radio frequency module and the communication device according to the present disclosure have been described above based on the embodiment. However, the exemplary radio frequency module and the communication device are not limited to the above embodiment. The exemplary aspects of the present disclosure may also include other embodiments realized by combining any of the components in the above embodiment, modifications obtained by making various changes to the above embodiment that can be conceived by those skilled in the art without departing from the spirit of the present disclosure, and various devices including the radio frequency module and communication device described above.

For example, in the circuit configuration of the radio frequency module and the communication device according to each example, other circuit elements, wiring, and the like may be inserted between the paths connecting the circuit elements and signal paths disclosed in the drawings.

The exemplary aspects of the present disclosure can be widely used in a communication device such as a mobile phone, as a radio frequency module or communication device disposed in a front end portion compatible with the millimeter wave band or the sub-terahertz band.

### REFERENCE SIGNS LIST

1, 1A, 1B, 1C, 1D, 1E, 1F, 1G RADIO FREQUENCY MODULE
2 TRACKER CIRCUIT
3 RFIC
4 COMMUNICATION DEVICE
10 CONVERTER CIRCUIT
10A CONVERTER SWITCH PORTION
20 SWITCHED-CAPACITOR CIRCUIT
20A SC SWITCH PORTION
22 ET VOLTAGE GENERATION CIRCUIT
22A ANALOG ET VOLTAGE GENERATION CIRCUIT
22B DIGITAL ET VOLTAGE GENERATION CIRCUIT
23 CONSTANT VOLTAGE GENERATION CIRCUIT
30 SUPPLY MODULATOR
30A SM SWITCH PORTION
40 FILTER CIRCUIT
50 POWER AMPLIFIER (PA)
51 LOW-NOISE AMPLIFIER
52, 53 PHASE SHIFT CIRCUIT
54 SWITCH
60A DIGITAL CONTROL PORTION
80, 80B, 80C INTEGRATED CIRCUIT
90 MODULE LAMINATE
90a, 90b MAIN SURFACE
91, 92 RESIN MEMBER
110, 131, 132, 133, 134, 140, 221, 231, 240, 501, 511 INPUT TERMINAL
111, 112, 113, 114, 118, 130, 141, 222, 232, 241, 242 OUTPUT TERMINAL
150 EXTERNAL CONNECTION TERMINAL
200 ANTENNA
223 ENVELOPE SIGNAL TERMINAL
224 FEEDBACK TERMINAL
225 LINEAR AMPLIFIER CIRCUIT
226 SYNTHESIS CIRCUIT
233 OUTPUT DRIVER CIRCUIT
234 OPERATIONAL AMPLIFIER CIRCUIT
235 FEEDBACK CIRCUIT
236 CONTROL TERMINAL
300 BBIC
301, 801 TERMINAL
400a, 400b MIXER
401, 402, 403, 404, 405, 406, 411, 412, 413, 414, 415, 416 WIRING
500 LOCAL OSCILLATOR

1. A radio frequency module comprising:
a module laminate;
a first integrated circuit on the module laminate and including at least one switch included in a converter circuit; and
a second integrated circuit on the module laminate and including a first amplifying transistor of a power amplifier that is configured to amplify a radio frequency signal, and a second amplifying transistor of a low-noise amplifier that is configured to amplify a radio frequency signal,
wherein the power amplifier is connected to an ET voltage generation circuit that is configured to generate a variable voltage based on an output voltage from the converter circuit and an envelope signal, and
wherein the low-noise amplifier is connected to a constant voltage generation circuit that is configured to generate a constant voltage based on the output voltage from the converter circuit.

2. The radio frequency module according to claim 1, wherein:
the constant voltage generation circuit includes an output driver circuit and an operational amplifier circuit,
the output driver circuit is configured to output, based on an output voltage from the operational amplifier circuit, a constant voltage that is lower than a maximum value of the output voltage from the converter circuit to the low-noise amplifier, and
the first integrated circuit further includes the output driver circuit.

3. The radio frequency module according to claim 1, wherein:
the ET voltage generation circuit includes a switched-capacitor circuit and a supply modulator,
the switched-capacitor circuit is configured to generate a plurality of discrete voltages based on the output voltage from the converter circuit, and further configured to output the generated plurality of discrete voltages to the supply modulator,
the supply modulator is configured to selectively output at least one discrete voltage of the generated plurality of discrete voltages as the variable voltage to the power amplifier, and
the first integrated circuit further includes at least one switch included in the switched-capacitor circuit and at least one switch included in the supply modulator.

4. The radio frequency module according to claim 3, wherein:
the module laminate has a first main surface and a second main surface that oppose each other, and
the first integrated circuit and the second integrated circuit are disposed adjacent to each other on the first main surface.

5. The radio frequency module according to claim 3,
wherein the first integrated circuit includes:
a first output terminal configured to output the variable voltage, and
a second output terminal configured to output the constant voltage, wherein the second integrated circuit includes:
a first input terminal connected to the power amplifier and the first output terminal, and
a second input terminal connected to the low-noise amplifier and the second output terminal, and
wherein a distance between the first output terminal and the first input terminal is smaller than a distance between the second output terminal and the second input terminal.

6. The radio frequency module according to claim 4, further comprising a filter circuit connected between the supply modulator and the power amplifier and configured to attenuate noise from the plurality of discrete voltages, wherein the filter circuit is disposed on the second main surface.

7. The radio frequency module according to claim 3, wherein:
the module laminate has a first main surface and a second main surface that oppose each other,
the first integrated circuit is on the second main surface, and
the second integrated circuit is on the first main surface.

8. The radio frequency module according to claim 7, wherein the first integrated circuit at least partially overlaps the second integrated circuit in a plan view of the module laminate.

9. The radio frequency module according to claim 7,
wherein the first integrated circuit includes:
a first output terminal configured to output the variable voltage, and
a second output terminal configured to output the constant voltage,
wherein the second integrated circuit includes:
a first input terminal connected to the power amplifier and the first output terminal, and
a second input terminal connected to the low-noise amplifier and the second output terminal, and
wherein the second integrated circuit at least partially overlaps the first output terminal in a plan view of the module laminate, and the second integrated circuit does not overlap the second output terminal in the plan view of the module laminate.

10. The radio frequency module according to claim 7, further comprising:
a filter circuit connected between the supply modulator and the power amplifier and configured to attenuate noise from the plurality of discrete voltages,
wherein the filter circuit is disposed on the first main surface, and adjacent to the power amplifier.

11. The radio frequency module according to claim 1, wherein:
the ET voltage generation circuit includes a linear amplifier circuit and a synthesis circuit,
the linear amplifier circuit is configured to linearly amplify an envelope signal and output a linearly amplified voltage to the synthesis circuit,
the synthesis circuit is configured to synthesize the linearly amplified voltage and the output voltage from the converter circuit to generate a variable voltage, and to output the generated variable voltage to the power amplifier, and
the first integrated circuit further includes the linear amplifier circuit.

12. The radio frequency module according to claim 11, wherein:
the module laminate has a first main surface and a second main surface that oppose each other, and
the first integrated circuit is disposed adjacent to the second integrated circuit on the first main surface.

13. The radio frequency module according to claim 11,
wherein the first integrated circuit includes:
a first output terminal configured to output the variable voltage, and
a second output terminal configured to output the constant voltage,
wherein the second integrated circuit includes:
a first input terminal connected to the power amplifier and the first output terminal, and
a second input terminal connected to the low-noise amplifier and the second output terminal, and
wherein a distance between the first output terminal and the first input terminal is smaller than a distance between the second output terminal and the second input terminal.

14. The radio frequency module according to claim 11, wherein:
the module laminate has a first main surface and a second main surface that oppose each other,
the first integrated circuit is on the second main surface, and
the second integrated circuit is on the first main surface.

15. The radio frequency module according to claim 14, wherein the first integrated circuit at least partially overlaps the second integrated circuit in a plan view of the module laminate.

16. The radio frequency module according to claim 14,
wherein the first integrated circuit includes:
a first output terminal configured to output the variable voltage, and
a second output terminal configured to output the constant voltage,
wherein the second integrated circuit includes:
a first input terminal connected to the power amplifier and the first output terminal, and
a second input terminal connected to the low-noise amplifier and the second output terminal, and
wherein the second integrated circuit at least partially overlaps the first output terminal in a plan view of the module laminate, and the second integrated circuit does not overlap the second output terminal in the plan view of the module laminate.

17. A radio frequency module comprising:
a module laminate;
a first integrated circuit on the module laminate and including:
a first output terminal configured to output a variable voltage, and
a second output terminal configured to output a constant voltage; and
a second integrated circuit on the module laminate and including:
a first input terminal connected to a power amplifier that is configured to amplify a radio frequency signal, and
second input terminal connected to a low-noise amplifier that is configured to amplify a radio frequency signal,
wherein the first output terminal is connected to the first input terminal, and the second output terminal is connected to the second input terminal.

18. The radio frequency module according to claim 17, wherein the second integrated circuit is a signal processing circuit configured to output a radio frequency signal.

19. The radio frequency module according to claim 17, wherein the power amplifier and the low-noise amplifier are configured to amplify signals in a millimeter wave band or a sub-terahertz band.

20. A communication device comprising:
a motherboard; and
the radio frequency module according to claim 1,
wherein the radio frequency module is disposed on the motherboard and is configured to transmit a radio frequency signal to an antenna.
